(19) United States
(12) Patent Application Publication
(10) Pub. No.: US 2026/0223512 A1
(43) Pub. Date: Jul. 30, 2026

(54) LIGHT EMITTING DISPLAY DEVICE

(71) Applicant: LG Display Co., Ltd., Seoul (KR)

(72) Inventors: Dong Chae SHIN, Gyeonggi-do (KR); Jun Ho LEE, Gyeonggi-do (KR); Sun Young CHOI, Gyeonggi-do (KR)

(21) Appl. No.: 19/252,871

(22) Filed: Jun. 27, 2025

(30) Foreign Application Priority Data
Jan. 24, 2025 (KR) 10-2025-0011988

(51) Int. Cl. H10H 29/852; G06F 3/044; H10H 29/37; H10H 29/85; H10H 29/855

(52) U.S. Cl. CPC H10H 29/852; G06F 3/0446; H10H 29/37; H10H 29/8517; H10H 29/8552; G06F 2203/04107; G06F 2203/04111

(57) ABSTRACT

A light emitting display device including a bank defining a plurality of light emitting portions spaced apart from each other on a substrate, a light emitting element including a first electrode, an intermediate layer and a second electrode on the first electrode provided in each of the light emitting portions, an encapsulation layer covering the light emitting element, a touch wiring disposed on the encapsulation layer, the touch wiring including a linear portion longer than a diameter of any one of the light emitting portions or a side of any one of the light emitting portions between the plurality of light emitting portions on a plane, a light-shielding layer covering the touch wiring on the encapsulation layer, and a color filter layer disposed on the encapsulation layer corresponding to each of the light emitting portions.

### CROSS REFERENCE TO RELATED APPLICATIONS

Pursuant to 35 U.S.C. § 119(a), this application claims the benefit of an earlier filing date and right of priority to Korean Patent Application No. 10-2025-0011988, filed on Jan. 24, 2025, the contents of which are hereby incorporated by reference in their entirety.

### TECHNICAL FIELD

The present disclosure relates to a light emitting display device.

### BACKGROUND

Display devices for displaying images are applied to single display devices such as TVs, monitors, smartphones, tablet PCs, and laptops, as well as at least one surface of devices having other functions such as vehicle panels, display glasses, wristwatches, and home appliances.

Among display devices, light emitting display devices that do not have a separate light source so as to miniaturize the devices and to represent clear color and have light emitting elements within the display panel are considered as competitive applications.

The display devices include a touch sensor unit in the upper part thereof to provide convenient operation.

### SUMMARY

According to an aspect of the present disclosure, a light emitting display device includes a bank defining a plurality of light emitting portions spaced apart from each other on a substrate, a light emitting element including a first electrode, an intermediate layer and a second electrode on the first electrode provided in each of the light emitting portions, an encapsulation layer covering the light emitting element, a touch wiring disposed on the encapsulation layer, the touch wiring including a linear portion longer than a diameter of any one of the light emitting portions or a side of any one of the light emitting portions between the plurality of light emitting portions on a plane, a light-shielding layer covering the touch wiring on the encapsulation layer, and a color filter layer disposed on the encapsulation layer corresponding to each of the light emitting portions.

It is to be understood that both the foregoing general description and the following detailed description of the present disclosure are examples and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure. In the drawings:

FIG. 1 is a plan view illustrating a display device according to an implementation of the present disclosure;

FIG. 2 is a cross-sectional view illustrating a state in which the display panel according to FIG. 1 is bent;

FIG. 3 is a circuit diagram illustrating a sub pixel of FIG. 1;

FIG. 4 is a plan view illustrating an area where subpixels SP of FIG. 1 are regularly disposed;

FIG. 5 is a cross-sectional view taken along line I-I′ of FIG. 4;

FIG. 6 is a cross-sectional view taken along line II-II′ of FIG. 4;

FIG. 7 is a cross-sectional view taken along line III-III′ of FIG. 4;

FIG. 8 is a cross-sectional view taken along line IV-IV′ of FIG. 3;

FIGS. 9 to 12 are plan views illustrating an area not overlapping a sensor unit of FIG. 1 according to another implementation;

FIG. 13 is a plan view illustrating an area overlapping with the sensor of FIG. 1; and

FIG. 14 is a cross-sectional view taken along the V-V′ line of FIG. 13.

### DETAILED DESCRIPTION

As technology advances and light emitting display devices have higher resolutions, the gap between adjacent light emitting portions becomes narrower and this may result in color-mixed light emitted from adjacent light emitting portions due to light emission from a predetermined light emitting portion.

The present disclosure relates to a light emitting display device that is capable of preventing color mixing between adjacent light emitting portions and also capable of reducing a thickness of a light-shielding layer by changing a structure of a touch wiring.

Implementations of the present disclosure can provide a light emitting display device that is capable of preventing color mixing between adjacent light emitting portions.

Implementations of the present disclosure can provide a light emitting display device that is capable of improving transmittance by omitting a polarizing plate from the upper part of an encapsulation layer.

Implementations of the present disclosure can provide a light emitting display device that is capable of preventing color mixing through the planar shape of the touch wiring disposed in the upper part of the encapsulation layer without changing a pixel definition film (bank) under the encapsulation layer.

Implementations of the present disclosure can provide a light emitting display device that is capable of reducing the thickness and size of a light-shielding layer through the color mixing-preventing function of the touch wiring disposed in the lower part than the light-shielding layer to increase transmittance.

Implementations of the present disclosure can provide a light emitting display device that is capable of disposing the light-shielding layer more freely in a structure including a sensor or camera under a substrate.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

Hereinafter, implementations will be described with reference to the drawings.

Like reference numbers refer to like components throughout the description of the figures. The thickness, ratio, size, and the like of components shown in the drawings to illustrate various implementations of the present disclosure are exaggerated for better illustration. The scale of the components shown in the drawings is different from the actual scale for better illustration and is therefore not limited to the scale shown in the drawings.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

It will be understood that, when an element (or a region, layer, film or part) is referred to as being “on”, “connected to” or “bound to” another element, it may be directly on, connected to or bound to the other element, or an intervening element may also be present therebetween.

The expression “and/or” includes all of one or more combinations that may be defined by the associated components.

The text “at least one of A or B” as used herein should be understood to include at least one of A, or at least one of B, or at least one of both A and B. This similarly applies to “at least one of A, B, or C” and so forth.

In describing the variety of implementations of the present disclosure, terms such as “first” and “second” may be used to describe a variety of components, but these terms only aim to distinguish the same or similar components from one another. Accordingly, throughout the disclosure, a “first” component may be referred to as a “second” component within the technical concept of the present disclosure. Similarly, a “second” component may be referred to as a “first” component within the technical concept of the present disclosure. Singular forms are intended to include plural forms as well, unless the context clearly indicates otherwise.

Spatially relative terms, such as “below”, “beneath”, “above”, and “upper”, may be used herein to describe the relationship between elements as shown in the figures. It will be understood that these terms are spatially relative and thus described based on the orientation depicted in the figures. For example, at least one intervening element may be present between the two elements, unless “immediately” or “directly” is used. Spatially relative terms, such as “below”, “beneath”, “above”, and “upper”, may be used herein to easily describe the correlation between one element or component and other elements or components. It will be understood that spatially relative terms are intended to encompass different orientations of a device during the use or operation of the device, in addition to the orientation depicted in the figures. For example, if a device in one of the figures is turned upside down, elements described as “below” or “beneath” other elements would then be positioned “above” the other elements. The example term “below” or “beneath” can, therefore, encompass the meanings of both “below” and “above”.

It will be further understood that the terms “comprises” and/or “has”, when used in this specification, specify the presence of stated features, integers, steps, operations, elements, parts or combinations thereof, but do not preclude the presence or addition of one or more other features, integers, steps, operations, elements, parts, or combinations thereof.

Features of various implementations of the present disclosure may be partially or completely integrated or combined with each other, and may be variously interoperated with each other and driven technically. The implementations of the present disclosure may be carried out independently from each other, or may be carried out together in an interrelated manner.

Hereinafter, the light emitting display device of the present disclosure will be described with reference to the attached drawings and implementations as follows.

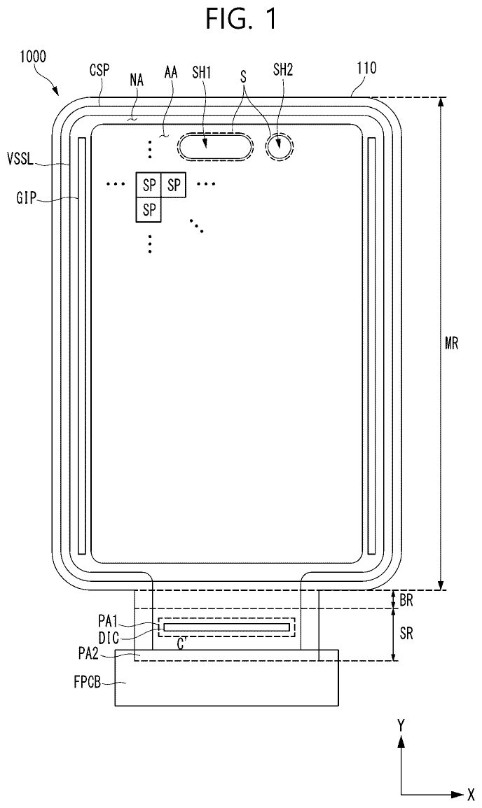

FIG. 1 is a plan view illustrating a display device according to an implementation of the present disclosure.

Referring to FIG. 1, a display device 1000 according to an implementation may include an active panel 100. The display panel 100 may include an active area AA including a plurality of sub-sub pixels SP, and a non-active area NA surrounding the active area AA. The planar shape of the active area AA may have a rectangular shape, but is not limited thereto. The planar shape of the active area AA may be a square, a circle, an oval, or other polygonal shape. For example, the active area AA may have a rectangular shape with rounded corners, but is not limited thereto and may also have a rectangular shape with sharp corners.

In some implementations, a first direction X and a second direction Y are different from each other and intersect each other. For example, the first direction X and the second direction Y intersect vertically in plan view. In FIG. 1, the first direction X may be generally the same as the extension direction of the short sides of the display panel 100 and the second direction Y may be the same as the extension direction of the long sides of the display panel 100. However, it should be understood that the directions described herein refer to relative directions and the implementations are not limited to the described directions.

The active area AA may include short sides extended in the first direction X and long sides extended in the second direction Y. The non-active area NA may surround the active area AA. The non-active area NA may be disposed on one side in the first direction X, the other side in the first direction X, one side in the second direction Y, and the other side in the second direction Y of the active area AA.

The display panel 100 may further include a sensor hole SH in which a sensor S overlaps the active area AA. The sensor S may be disposed on the lower side of the display panel 100 and may have a larger shape than the sensor holes (SH1, SH2). The number of sensor holes SH1 and SH2 may be two, for example, as shown in FIG. 1, but the implementations of the present disclosure are not limited thereto. For example, the number of the sensor hole may be one. The two sensor holes SH1 and SH2 may include a sensor hole in which an infrared sensor is disposed and a sensor hole in which a camera sensor is disposed, respectively, but the implementations of the present disclosure are not limited thereto. A sensor non-active area may be present between the sensor holes SH1 and SH2, and the active area AA. The sensor non-active area may completely surround the sensor holes SH1 and SH2. A subpixel SP may not be disposed in the sensor non-active area.

In some cases, the sensor hole may be not disposed and the sensors may overlap each other in the display panel. In this case, the sensor S and the subpixels SP may partially overlap. The area of the subpixel SP that overlaps the sensor is referred to as a “sensor unit”.

A gate driver GIP may be disposed in the non-active area NA disposed on one side in the first direction X and the other side in the first direction X of the active area AA. A low-potential voltage line VSSL may be disposed on the outside of the gate driver GIP in the non-active area NA. For example, as shown in FIG. 1, the low-potential voltage line VSSL may extend from a flexible printed circuit board FPCB, pass through a sub-region SR and a bending region BR, be disposed on the outside of the gate driver GIP in the non-active area NA and surround the active area AA.

The non-active area NA disposed on the other side in the second direction Y of the active area AA may further extend in the other direction of the second direction Y in the center of the other side of the second direction Y of the active area AA. The width in the first direction X of the non-active area NA that extends further in the other direction of the second direction Y in the center of the other side of the second direction Y of the active area AA may be smaller than the width in the first direction X of the non-active area NA adjacent to the other side of the second direction Y of the active area AA.

The light emitting display device 1000 may include a main region MR, a sub-region SR, and a bending region BR between the main region MR and the sub-region SR. The active area AA and the non-active area NA that surrounds the active area AA on four sides may constitute the main region MR, and the portion that extends further in the other direction of the second direction Y in the center of the other side of the second direction Y of the active area AA may constitute the bending region BR and the sub-region SR. The bending region BR may be disposed between the sub-region SR and the main region MR. The sub-region SR may include a first pad area PA1 and a second pad area PA2 disposed at the other end in the second direction Y of the sub-region SR. The display device 1000 may further include a data driver DIC and a flexible printed circuit board FPCB. The data driver DIC may be disposed in the first pad area PA1 and the flexible printed circuit board FPCB may be attached to the second pad area PA2. A plurality of pads connected to the data driver DIC and the flexible printed circuit board FPCB may be disposed in the first pad area PA1 and the second pad area PA2, respectively. The data driver DIC may take the form of, for example, a driving chip IC, but is not limited thereto. In one implementation, the data driver DIC is directly mounted on the display panel 100 in a chip-on-plastic manner, but is not limited thereto and may be disposed in a chip-on-glass manner or a chip-on-film manner.

The display panel 100 according to one implementation may further include a crack sensor pattern CSP surrounding the low-potential voltage line VSSL. The crack sensor pattern CSP may be disposed to completely surround the active area AA, as shown in FIG. 1. For example, the crack sensing pattern CSP may be disposed outside of the low-potential voltage line VSSL. However, the implementations of the present disclosure are not limited thereto and the crack sensor pattern CSP may not be disposed in some of the non-active area NA on the other side in the second direction Y of the active area AA.

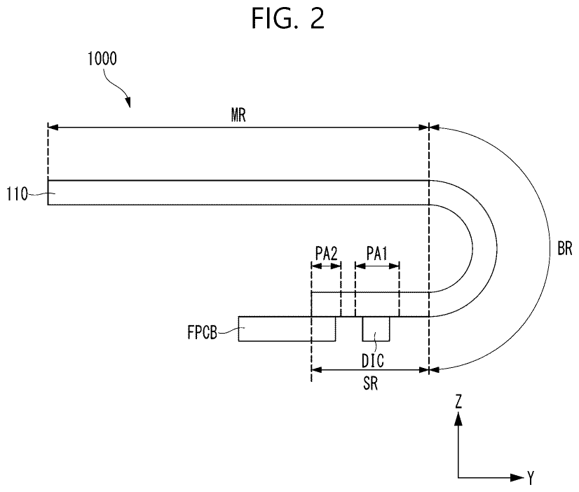

FIG. 2 is a cross-sectional view illustrating a state in which the display panel illustrated with reference to FIG. 1 is bent.

Referring to FIG. 2, the bending region BR of the display panel 100 of the display device 1000 according to one implementation may be bent in a thickness direction (or a third direction (Z)). As a result, the main region MR and the sub-region SR may overlap in the thickness direction. The display panel 100 may be bent such that the lower surface of the main region MR faces the upper surface of the sub-region SR. A flexible printed circuit board FPCB may be attached to the end of the sub-region SR.

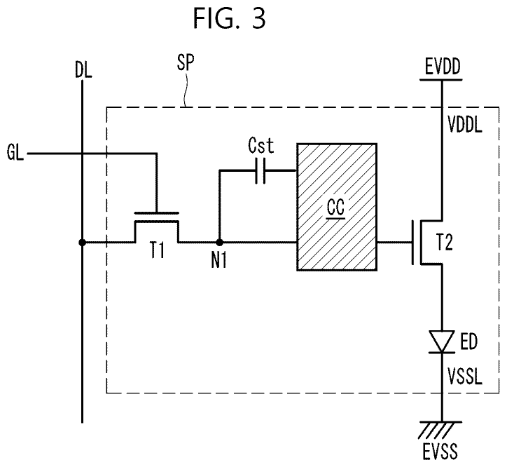

FIG. 3 is a circuit diagram illustrating the subpixel of FIG. 1.

The active area AA and the non-active area NA of the light emitting display device 1000 may be applied to the substrate 110 in the same manner.

For example, a plurality of data lines DL extending in the second direction Y and a plurality of gate lines GL extending in the first direction X may be disposed in the active area AA on the substrate 110.

Each of the areas defined by the intersection of the data lines DL and the gate lines GL may constitute a subpixel SP. One subpixel SP may be defined as an area where a light emitting portion is disposed. However, in the implementations of the present disclosure, the light emitting portion is not necessarily limited to an area defined by the intersection of the data wire DL and the gate line GL. That is, at least a part of the light emitting portion may intersect the data line DL and/or the gate line GL.

The subpixel SP is disposed between gate lines GL and data lines DL that intersect each other, as shown in FIG. 3, and may include a first transistor T1, a second transistor T2, a storage capacitor Cst, a compensation circuit CC, and a light emitting element ED.

For example, the first transistor T1 may be a switching transistor and the second transistor T2 may be a driving transistor.

Each of the first transistor T1 and the second transistor T2 may include an active layer, a gate electrode, and first and second source-drain electrodes. The active layer of at least one of the first and second transistors T1 and T2 may include at least one of amorphous silicon, crystalline silicon, or an oxide semiconductor. The active layer of at least one of the first or second transistor T1 and T2 may include an oxide semiconductor. For example, the oxide semiconductor may contain an oxide semiconductor material such as IGZO (indium-gallium-zinc-oxide).

The first transistor T1 is electrically connected to the data line DL and is electrically connected to the first node N1. The gate electrode of the first transistor T1 is electrically connected to the gate line GL. The first transistor T1 transmits, to the first node N1, a data signal supplied through the data line DL in response to a scan signal supplied through the gate line GL.

The storage capacitor Cst is electrically connected to the first node N1 and charges a voltage applied to the first node N1.

The second transistor T2 receives a high-potential driving voltage EVDD and is electrically connected to a first electrode (e.g., anode) of the light emitting element ED. The second transistor T2 may control the amount of driving current flowing to the light emitting element ED in response to the voltage applied to the gate electrode. The high potential driving voltage EVDD may be connected to the second transistor T2 through a first power supply voltage line VDDL.

The light emitting element ED outputs light in response to the driving current supplied from the second transistor T2. The light emitting element ED may emit red, green, blue, or white light.

The light emitting element ED includes a first electrode, an intermediate layer disposed on the first electrode, and a second electrode. The second electrode of the light emitting element ED may be connected to a second power supply voltage line VSSL that supplies the low potential driving voltage (EVSS). The second power supply voltage line VSSL may be disposed in the non-active area NA and connected to the second electrode. In some cases, the second power supply voltage line VSSL is also disposed in the active area AA to supply a low-voltage driving voltage (EVSS) to each subpixel SP or multiple subpixels SP and to uniformize the potential of the second electrode of the respective subpixels.

The intermediate layer includes a light emitting layer and various functional layers, and may be designed to emit light of the same color, such as white light, for each pixel, or may be designed to emit different colors such as red, green, and blue light for the subpixels SP. The functional layers may include a hole injection layer, a hole transport layer, an electron transport layer, an electron injection layer, a charge generation layer, or the like. The intermediate layer may include a plurality of stacks, and the plurality of stacks may have a charge generation layer between adjacent stacks to smoothly supply holes and electrons to both stacks. Each of the plurality of stacks may include at least one light emitting layer, a hole transport layer and an electron transport layer.

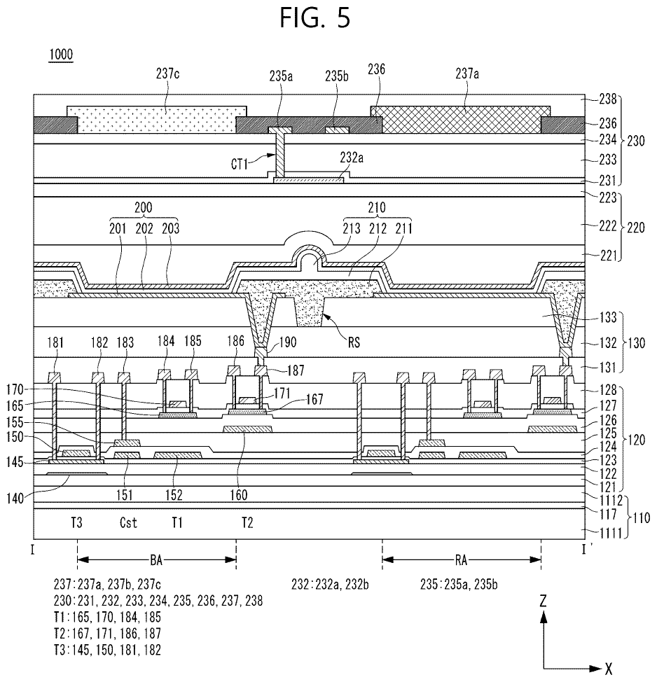

The first electrode may act as an anode, and the second electrode may act as a cathode. The light emitting element ED is substantially the same as the light emitting element (200: see FIG. 5) described below.

The compensation circuit CC may be provided in a first subpixel (SP1) to compensate for the threshold voltage of the second transistor T2 or the like. The compensation circuit CC may include one or more transistors. The compensation circuit CC may include one or more transistors and one or more capacitors, and may be configured in various forms depending on the compensation method. The pixel including the compensation circuit CC may have various structures such as 3T1C, 4T2C, 5T2C, 6T1C, 6T2C, 7T1C, and 7T2C. For example, a plurality of transistors may be electrically connected between the second transistor T2 and the light emitting element ED.

Although FIG. 3 illustrates a configuration in which the second transistor T2 is directly connected to the light emitting element ED, the implementations of the present disclosure are not limited thereto. Depending on the form of the compensation circuit CC, the light emitting element ED may further include another transistor or compensation capacitor between the compensation circuit CC and the second transistor T2 that generates the driving current.

Meanwhile, in the active area AA in FIG. 1, the light emitting portions may be regularly disposed in the area that does not overlap the sensor S. The arrangement density of the light emitting portions in the area where at least one sensor S is disposed may be reduced in the area that does not overlap with the sensor S. Hereinafter, the area that does not overlap the sensor S is referred to as “area A”, and the area that overlaps the sensor S is referred to as “area B”, and the following descriptions will be provided in order.

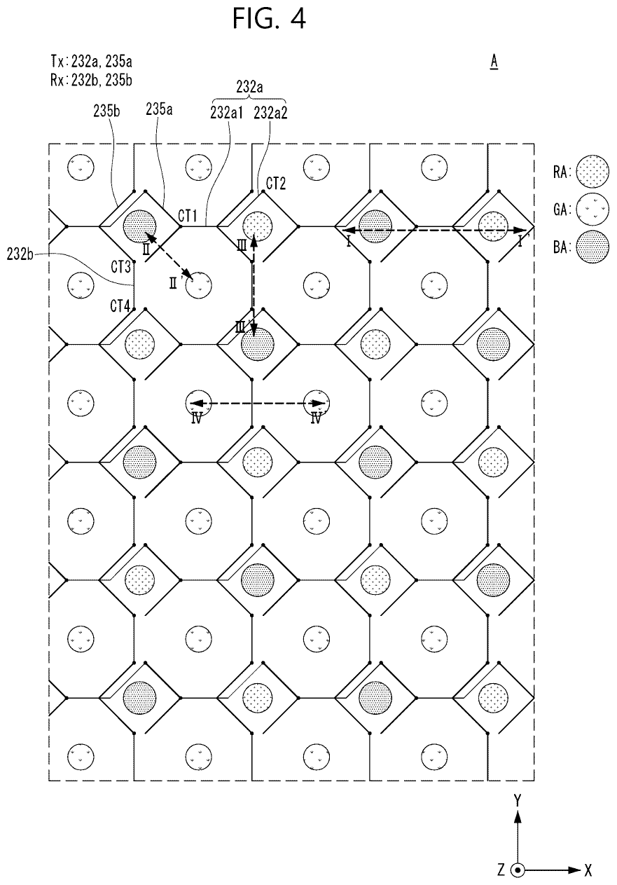

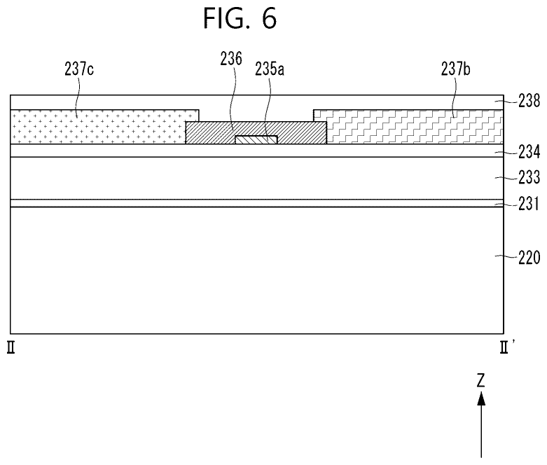

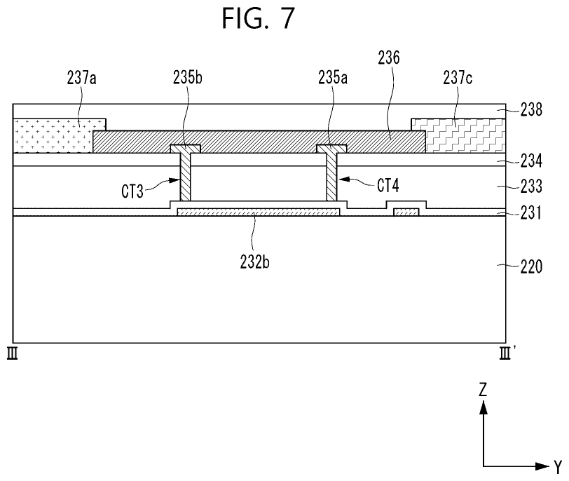

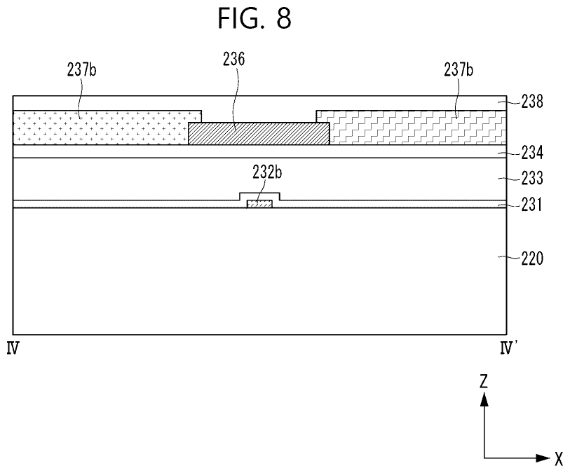

FIG. 4 is a plan view illustrating the active area that does not overlap the sensor of FIG. 1. FIG. 5 is a cross-sectional view taken along line I-I′ of FIG. 4. FIG. 6 is a cross-sectional view taken along line II-II′ of FIG. 4. FIG. 7 is a cross-sectional view taken along line III-III′ of FIG. 4. FIG. 8 is a cross-sectional view taken along line IV-IV′ of FIG. 3.

As shown in FIGS. 4 to 8, a light emitting display device 1000 according to an implementation of the present disclosure includes a bank 210 defining a plurality of light emitting portions RA, GA and BA spaced apart from each other on a substrate 110, a light emitting element 200 disposed on the substrate 110, an encapsulation layer 220 covering the light emitting element 200, and a touch sensor and a color filter unit TCOE (230) disposed on the encapsulation layer.

The plurality of light emitting portions RA, GA and BA may be disposed in regions partitioned on the substrate 110, and one light emitting portion RA, GA or BA may be disposed for each subpixel. The light emitting color emitted from the light emitting portion RA, GA or BA may be determined by the light emitting layer included in the light emitting element 200 and the color filter layer (237: 237a, 237b, 237c) provided in the touch sensor and color filter portion TCOE.

The plurality of light emitting portions RA, GA and BA may include, for example, a red light emitting portion RA, a green light emitting portion GA, and a blue light emitting portion BA. In addition, the light emitting portions may further include a white light emitting portion.

The example shown in FIG. 4 shows a configuration in which the red light emitting portion RA and the blue light emitting portion BA are disposed alternately in the X-axis direction and the Y-axis direction, and the green light emitting portion GA is disposed between one red light emitting portion RA and one blue light emitting portion BA in the X-axis direction and between one red light emitting portion RA and one blue light emitting portion BA in the Y-axis direction. In this case, the green light emitting portion GA is disposed at the center of a virtual square in which a red light emitting portion RA or a blue light emitting portion BA is disposed at each corner thereof.

In the illustrated example, the red, green, and blue light emitting portions RA, GA and BA each have a circular shape, but this is merely provided as an example, and the implementations of the present disclosure are not limited thereto. The red, green, and blue light emitting portions RA, GA and BA may independently take the shape of any one of a circle, an ellipse, and a polygon. Alternatively, the red, green, and blue light emitting portions RA, GA and BA may have a mixed configuration in which a part of the outline is curved and the residue of the outline is straight. The red light emitting portion RA, the green light emitting portion GA, and the blue light emitting portion BA may have the same shape, or at least a part of the light emitting portions may have different shapes. The shape, arrangement density, and size (area) of the red, green, and blue light emitting portions RA, GA and BA may vary depending on the model of the light emitting display device or the target brightness or efficiency of the light emitting display device.

The sizes (areas) of the red, green, and blue light emitting portions RA, GA and BA may be different from each other. For example, the size of the blue light emitting portion BA may be the largest and the size of the green light emitting portion GA may be the smallest. When the size of the light emitting portion is large, it may compensate for the relatively low luminance efficiency compared to other colors, but the implementations of the present disclosure are not limited thereto.

At least a light emitting element 200 is disposed on the substrate 110 in the light emitting portion RA, GA or BA so that the light emitting portion RA, GA or BA emits light. The light emitting element 200 includes a first electrode 201, an intermediate layer 202, and a second electrode 203. The light emitting portion RA, GA or BA may have an area defined by a bank 210. The bank 210 is also referred to as a “pixel-defining film” and may be provided by exposing the light emitting portion RA, GA or BA of the first electrode 201 of the light emitting element 200. The edge of the first electrode 201 excluding the light emitting portion RA, GA or BA may overlap the bank 210.

Meanwhile, the touch sensor and color filter unit TCOE of the present disclosure function as the touch sensor and the color filter unit, respectively, and are disposed on the upper part of the encapsulation layer 220. Therefore, the light emitting display device according to the implementation of the present disclosure may make the total thickness of the configuration provided as a functional layer on the encapsulation layer 220 thin. For example, when the touch sensor having a plurality of touch wiring layers and the color filter unit including the light-shielding layer and the color filter layer are provided separately for the functional units, a base substrate may be included for each functional unit and a component such as an adhesive layer between the functional units may be required. In the implementation of the present disclosure, the touch sensor and color filter unit TCOE is formed by depositing an insulating film, a wiring layer, a light-shielding layer, and a color filter layer on the encapsulation layer 220 and thus the base substrate may be omitted, and the adhesive layer and the adhesive process may be omitted.

The touch sensor and color filter unit TCOE (230) may include, from the bottom up, a touch buffer layer 231, a bridge layer (232: 232a, 232b), a first touch intermediate insulating film 233, a second touch intermediate insulating film 234, a sensor electrode (235: 235a, 235b), a light-shielding layer 236, a color filter layer (237: 237a, 237b, 237c), and an upper protective layer 238.

The bridge layer (232: 232a, 232b) may be protected by the touch buffer layer 231.

The touch buffer layer 231, the first and second touch intermediate insulating films 233 and 234, and the upper protective layer 238 may include a transparent inorganic insulating film or a transparent organic insulating film. Since the touch buffer layer 231 is flattened by the encapsulation layer 220 disposed thereunder, the touch buffer layer 231 in the touch sensor and the color filter unit TCOE may be formed as an inorganic insulating film. The inorganic insulating film of the touch buffer layer 231 may be, for example, a silicon nitride film, a silicon oxide film, or a silicon oxynitride film. Since the first and second sensor electrodes 235a and 235b, the light-shielding layer 236, and the color filter layers (237: 237a, 237b, 237c) commonly use the upper surface of the second touch intermediate insulating film 234 as a formation surface, at least one of the first and second touch intermediate insulating films 233 and 234 may include an organic insulating film to flatten the surface.

The color filter layer 237 may include a red filter layer 237a corresponding to an area having a red light emitting portion RA, a green filter layer 237b corresponding to an area having a green light emitting portion GA, and a blue filter layer 237c corresponding to an area having a blue light emitting portion BA.

The widths of the red filter layer 237a, the green filter layer 237b, and the blue filter layer 237c are larger than the widths of the respective light emitting portions RA, GA and BA so as to partially overlap the light-shielding layer 236. The red filter layer 237a, the green filter layer 237b, and the blue filter layer 237c may each overlap the light-shielding layer 236 and thus further improve the effect of preventing external light visibility and color mixing between adjacent light emitting portions.

In the touch sensor and color filter unit TCOE, the light shielding layer 236 may block light of the entire wavelength range of visible light. The color filter layer (237: 237a, 237b, 237c) may transmit light of a predetermined wavelength range and block light of the remaining wavelength range. The light shielding layer 236 and the color filter layer (237: 237a, 237b, 237c) may prevent external light travelling from the upper protective layer 238 from being reflected by the first electrode 201 of the light emitting element 200 inside the light emitting display device 1000 based on the light shielding function. Therefore, the polarizing plate provided on the outermost side of the light emitting display device may be omitted and the transmittance of light emitted from the light emitting display device may be increased by omitting the polarizing plate.

Meanwhile, in the light emitting display device according to the implementation of the present disclosure, the bridge layer (232: 232a, 232b) and the sensor electrode (235: 235a, 235b) contain a low-reflectivity metal. For example, the bridge layer (232: 232a, 232b) and the sensor electrode (235: 235a, 235b) may contain a metal or alloy including at least one of titanium (Ti), molybdenum (Mo), chromium (Cr), or aluminum (Al).

A touch wiring including bridge layers (232: 232a, 232b) and sensor electrodes (235: 235a, 235b) are disposed around each light emitting portion RA, GA or BA, and block the light emitting portions to prevent color mixing between adjacent light emitting portions so that the thickness of the light-shielding layer 236 disposed between the light emitting portions RA, GA and BA may be made thin. In addition, the light-shielding layer should have a large formation margin in proportion to the thickness thereof. By reducing the thickness of the light-shielding layer 236, the formation margin may be reduced. Therefore, in the light emitting display device according to the implementation of the present disclosure, the width of the light-shielding layer 236 may be designed to correspond to the width of the bank 210 disposed on the lower side and the light-shielding layer 236 does not encroach on the light emitting portion. According to an implementation of the present disclosure, the light emitting display device may increase the luminous efficiency of the light emitting element by reducing the thickness and width of the light-shielding layer 236 since the touch wiring including the bridge layer (232: 232a, 232b) and the sensor electrode (235: 235a, 235b) functions to prevent color mixing between adjacent light emitting portions and has freedom of design of the light-shielding layer open area due to the function of preventing color mixing of the touch wiring.

In the light emitting display device 1000 according to an implementation of the present disclosure, the touch wiring including the bridge layer (232: 232a, 232b) and the sensor electrode (235: 235a, 235b) is disposed at least between the light emitting portions, as shown in FIG. 3.

In terms of application of an electrical signal with reference to FIG. 4, the touch wiring may include a transport electrode Tx that transmits a touch sensing signal and a transmission electrode Rx that receives a touch detection signal. The transport electrode Tx and the transmission electrode Rx cross each other on the encapsulation layer 220. The transport electrode Tx may be referred to as a “first touch wire” and the transmission electrode Rx may be referred to as a “second touch wire”.

In the example of FIG. 4, the transport electrode Tx and the transmission electrode Rx are disposed in the first direction X, i.e., along the X-axis, and in the second direction Y, i.e., along the Y-axis, respectively. In some cases, the transmission electrode Rx may be disposed in the X-axis direction and the transport electrode Tx may be disposed in the Y-axis direction.

The following description will be given based on the configuration shown in FIG. 3.

The transport electrodes Tx are spaced apart from each other in the X-axis direction and include a plurality of first sensor electrodes 235a in an island shape and a first bridge layer 232a connecting adjacent first sensor electrodes 235a.

The transmission electrodes Rx are spaced apart from each other in the Y-axis direction and include a plurality of second sensor electrodes 235b in an island shape and a second bridge layer 232b connecting adjacent second sensor electrodes 235b.

Referring to FIG. 3, at least a part of the first bridge layer 232a, the second bridge layer 232b, the first sensor electrode 235a, and the second sensor electrode 235b are disposed around (e.g., surround) a light emitting portion RA, GA or BA such that a part of the touch wiring Rx or Tx is diposed around (e.g., surrounds) the light emitting portion RA, GA or BA.

For example, as shown in FIG. 4, in the red light emitting portion RA or the blue light emitting portion BA, the first sensor electrode 235a and the second sensor electrode 235b are disposed on the right and left sides of each light emitting portion RA or BA and are disposed to be symmetrical. For example, as shown in FIG. 4, the first and second sensor electrodes 235a and 235b may form a diamond shape that surrounds the red light emitting portion RA or the blue light emitting portion BA.

When the first and second sensor electrodes 235a and 235b are disposed on the same layer, the first sensor electrode 235a and the second sensor electrode 235b are separated from each other for electrical separation.

Each first sensor electrode 235a adjacent to one light emitting portion and the next light emitting portion in the X-axis direction has an island shape and a first bridge layer 232a may be provided in a different layer from the first sensor electrode 235a to electrically connect the first sensor electrodes 235a adjacent to different light emitting portions. Since the second sensor electrode 235b is disposed between one first sensor electrode 235a and another first sensor electrode 235a adjacent thereto in the X-axis direction, the first bridge layer 232a overlaps the second sensor electrode 235b disposed on the path between the adjacent first sensor electrodes 235a, but is not connected.

Since the first bridge layer 232a passes through the light emitting portion when connecting one first sensor electrode 235a to the next first sensor electrode 235a adjacent thereto in a straight line in the X-axis direction, the first bridge layer 232a is disposed to be adjacent to the light emitting portion BA, GA or RA, but bypass the light emitting portion so as to prevent loss of opening of the light emitting portion.

For example, the first bridge layer 232a between adjacent blue light emitting portion BA and red light emitting portion RA may include a first linear portion 232a1 that is connected to the first sensor electrode 235a adjacent to the blue light emitting portion BA through a first contact portion CT1, overlaps the second sensor electrode 235b disposed adjacent to the left side of the red light emitting portion RA, is not connected to the second sensor electrode 235b, and extends in the X-axis direction, and a second linear portion 232a2 that is connected to the first sensor electrode 235a that is disposed adjacent to the right side of the red light emitting portion RA from the first linear portion 232a1 through a second contact portion CT2. Each of the first and second linear portions 232a1 and 232a2 may be a straight line. The regions of the first contact portion CT1 and the second contact portion CT2 may be changed by changing the overlapping area of the first bridge layer 232a in a region where the first sensor electrode 235a is adjacent to the neighboring light emitting portions. For example, the first contact portion CT1 may be disposed in an area other than the center of the illustrated first sensor electrode 235a. The second contact portion CT2 is disposed at one end of the first sensor electrode 235a as shown in FIG. 4, but this is merely provided as an example, and the second contact portion CT2 may be disposed in an area other than the one end of the first sensor electrode 235a.

Here, the second linear portion 232a2 of the first bridge layer 232a may be disposed closer to the light emitting portion RA or BA than the second sensor electrode 235b.

In some cases, the first transport electrode Tx may be formed by omitting the second linear portion 232a2 from the first bridge layer 232a and extending the first sensor electrode 235a in the same plane shape as the second linear portion 232a2, and may be provided with a second contact portion CT2 in which the extended first sensor electrode 235a and one end of the first linear portion of the first bridge layer are connected. In other words, the second linear portion may be disposed in a layer to form a sensor electrode, not a bridge layer.

In addition, the island-shaped second sensor electrodes 235b disposed in the Y-axis direction are connected to the second bridge layer 232b through a third contact portion CT3 disposed on one side thereof and a fourth contact portion CT4 disposed on the other side thereof, as shown in FIG. 7.

The first to fourth contact portions CT1, CT2, CT3 and CT4 may be provided in the form of a contact hole within the first and second touch intermediate insulating films 233 and 244 as shown in FIGS. 5 to 8.

As shown in FIG. 4, at least one of the first and second bridge layers 232a and 232b and the first and second sensor electrodes 235a and 235b is provided between different light emitting portions RA, GA and BA. The light generated from the light emitting portions RA, GA and BA may be direct light directed upward as well as oblique light. When such oblique light is observed from an adjacent light emitting portion, it may be mixed with direct light from an adjacent light emitting portion, resulting in mixed light emission, which may deteriorate the image quality. The first and second bridge layers 232a and 232b, and the first and second sensor electrodes 235a and 235b of the light emitting display devices of the implementations of the present disclosure are disposed at least partially between adjacent light emitting portions so as to block light emitted in a diagonal direction from one of the light emitting portions.

As shown in FIGS. 5 to 8, the first and second bridge layers 232a and 232b are disposed on the same layer and the first and second sensor electrodes 235a and 235b are disposed on the same layer so as to minimize the number of wires required for touch wiring.

The first and second bridge layers 232a and 232b and the first and second sensor electrodes 235a and 235b may each contain a metal or alloy including at least one of titanium, molybdenum, chromium, or aluminum.

The first and second bridge layers 232a and 232b and the first and second sensor electrodes 235a and 235b have a thin line shape having a width thinner than the width of the light-shielding layer 236 or the diameter of the light emitting portions RA, GA and BA. Although the first and second bridge layers 232a and 232b and the first and second sensor electrodes 235a and 235b have a thin line shape, they include a linear type portion that is longer than the diameter of one of the light emitting portions or one side of one of the light emitting portions between different light emitting portions and thus effectively blocks oblique light between the light emitting portions. In the example of FIG. 4, the light emitting portions RA, GA and BA have a circular shape and thus the critical dimension of the light emitting portions RA, GA and BA corresponds to the diameter of each light emitting portion RA, GA or BA. At least one of the touch wirings of the first and second bridge layers 232a and 232b and the first and second sensor electrodes 235a and 235b is disposed in a cross-section cut in any direction between different light emitting portions, so that the linear portion of the touch wiring blocks light emitted in a diagonal direction from one of the light emitting portions.

The first and second sensor electrodes 235a and 235b and the first linear portion 232a1 of the first bridge layer 232a are disposed between the red light emitting portion RA and the blue light emitting portion BA adjacent to each other in the X-axis direction. The first sensor electrode 235a or the second sensor electrode 235b is disposed between the red light emitting portion RA and the green light emitting portion GA. The first sensor electrode 235a or the second sensor electrode 235b is disposed between the blue light emitting portion BA and the green light emitting portion GA. The first bridge layer 232a or the second bridge layer 232b is disposed between the green light emitting portions GA.

The first and second sensor electrodes 235a and 235b, the second linear portion 232a2 of the second bridge layer 232b, and the first bridge layer 232a are disposed between the adjacent blue light emitting portions BA and red light emitting portions RA in the Y-axis direction. The first and second sensor electrodes 235a and 235b may have openings on one side of the blue light emitting portion BA and one side of the red light emitting portion RA for electrical separation from each other, and at least the second bridge layer 232b and the second linear portion 232a2 of the first bridge layer 232a are disposed in the openings to prevent the oblique light from each light emitting portion BA or RA from being observed in the adjacent light emitting portion.

The shape of the illustrated first bridge layer 232a is merely provided as an example and the first bridge layer 232a may have a different shape as long as it overlaps the second sensor electrode 235b disposed in the path between the adjacent first sensor electrodes 235a, but is not connected.

The first and second sensor electrodes 235a and 235b are provided in the form of islands corresponding to the respective light emitting portions.

An example in which the bridge layer (232: 232a, 232b) is disposed on the lower side in the stacked configuration of the touch wiring of FIGS. 5 to 8 is illustrated, and the sensor electrode (235: 235a, 235b) is disposed on the upper side, but this is merely provided as an example, and the bridge layer may be disposed on the upper side and the sensor electrode may be disposed on the lower side.

The light-shielding layer 236 is provided to cover at least the first and second bridge layers (232: 232a, 232b) and the first and second sensor electrodes (235: 235a, 235b). The light-shielding layer 236 is disposed in an area excluding the light emitting portion RA, GA or BA so as to correspond to the bank 210 defining the light emitting portion RA, GA or BA.

Hereinafter, the configuration of the lower side of the touch sensor and color filter portion TCOE will be described in more detail.

Referring to FIG. 1, a plurality of subpixels SP are provided in the active area AA of the substrate 110, and each of the plurality of subpixels SP includes a light emitting portion RA, GA or BA, and a non-light emitting portion disposed outside the light emitting portion RA, GA or BA.

The substrate 110 is formed of a flexible material and is thus easily removed when irradiated with a laser to form a hole H. For example, the substrate 110 may be formed of first and second organic films 1111 and 1112 that overlap each other with an inorganic interlayer insulating film 117 therebetween. The inorganic interlayer insulating film 117 may function to block the transfer of moisture or impurities between the first and second organic films 1111 and 1112. The inorganic interlayer insulating film 117 may be formed on the first organic film 1111 and may include a partially patterned component. The inorganic interlayer insulating film 117 may include at least one of a silicon nitride film, a silicon oxide film, or a silicon oxynitride film.

The first and second organic films 1111 and 1112 may include, for example, polyimide or polyethylene terephthalate (PET). The first and second organic films 1111 and 1112 may include an organic material other than polyimide.

The substrate 110 may contain PET (polyethylene terephthalate) for one of the first and second organic films 1111 and 1112 and polyimide for the other.

As another example, the substrate 110 may contain a thin glass material having flexibility.

The substrate 110 functions to support and protect components of the display device disposed thereon.

A plurality of stacked insulating films (120: 121, 122, 123, 124, 125, 126, 127, 128) and planarization films (130: 131, 132 and 133) are disposed on the active area AA and the non-active area NA of the substrate 110. These insulating films 120 and the planarization film (130: 131, 132, 133) insulate electrodes or active layers as different layers from each other in the stack configuration of the transistors T1, T2 and T3, and the storage capacitor Cst.

As shown in FIG. 5, the first to third transistors T1, T2 and T3 and the storage capacitor Cst may be disposed on the substrate 110. The first transistor T1 may function as a switching transistor as shown in FIG. 2, and the second transistor T2 may function as a driving transistor. The third transistor T3 is a switching transistor to which a gate signal or emission control signal different from that of the first transistor T1 is applied and may be provided in a gate driving unit included in a subpixel or disposed in a non-active area NA.

The first transistor T1 may include a first active layer 165, a first gate electrode 170, and first and second source-drain electrodes 184 and 185.

The second transistor T2 may include a second active layer 167, a second gate electrode 171, and third and fourth source-drain electrodes 186 and 187.

The third transistor T3 may include a third active layer 145, a third gate electrode 150, and fifth and sixth source-drain electrodes 181 and 182.

The first and second active layers 165 and 167 of the first and second transistors T1 and T2 may be disposed on the same layer and may include an oxide semiconductor layer. In this case, the off-current characteristics of the first and second transistors T1 and T2 may be stabilized.

The third active layer 145 of the third transistor T3 may be disposed on a different layer from the first and second active layers 165 and 167 and may contain crystalline silicon. In this case, the third transistor T3 may have high mobility and thus be advantageous for high-speed driving. The third transistor T3 may be disposed in a gate driving unit of the non-active area NA rather than in the active area AA as shown in FIG. 4.

The first to third transistors T1, T2 and T3 may include first to third light-shielding patterns 152, 160 and 140, respectively, to prevent abnormal phenomenon such as generation of photocurrent in the first to third active layers 165, 167 and 145 due to light travelling from the lower side of the substrate 110.

The first to third transistors T1, T2 and T3 may have different characteristics depending on stack configurations thereof.

The storage capacitor Cst may include the first and second storage electrodes 151 and 155 disposed on the same layer as at least one of the electrodes among the first to third transistors T1, T2 and T3 and the first to third light-shielding patterns 152, 160 and 140. For example, the first storage electrode 151 may be disposed on the same layer as the third gate electrode 150 and the first light-shielding pattern 152 of the third transistor T3.

The second transistor T2 may be connected to the first electrode 201 of the light emitting element 200 through the connection electrode 190.

The insulating film 120 provided on the substrate 110 may include, for example, a first insulating film 121, a second insulating film 122, a third insulating film 123, a fourth insulating film 124, a fifth insulating film 125, a sixth insulating film 126, a seventh insulating film 127, and an eighth insulating film 128. The insulating film 120 may contain an inorganic insulating material.

The first insulating film 121 is disposed on the active area AA and the non-active area NA on the substrate 110. The first insulating film 121 may be referred to as a “buffer film” and may have the same function as a buffer film. The first insulating film 121 may be disposed on the substrate 110 and thus protect structures located on the upper portion of the substrate 110 from moisture penetrating through the substrate 110 and flatten the surface of the substrate 110. The first insulating film 121 may include a plurality of inorganic insulating films.

The first insulating film 121 may be disposed up to the edge of the non-active area NA of the substrate 110 to prevent moisture from penetrating from the edge of the substrate 110. The first insulating film 121 may be a single inorganic film or may include a plurality of inorganic films that are alternately stacked.

For example, the first insulating film 121 may include at least one inorganic film of a silicon oxide film (SiOx), a silicon nitride film (SiNx), or a silicon oxynitride film (SiOxNy), or may include multiple layers in which the inorganic films described above are stacked.

For example, the third light-shielding pattern 140 may be provided on the first insulating film 121. For example, the first light-shielding pattern 140 may be formed of a conductive metal material. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum TA, neodymium (Nd), or titanium (Ti).

A second insulating film 122 may be disposed on the first insulating film 121. The second insulating film 122 may function as, for example, a second buffer layer. A transistor provided on the substrate 110 may include a polysilicon transistor having an active layer formed of crystalline silicon. In this case, the second insulating film 122 may stabilize and planarize the formation surface of the active layer including crystalline silicon. The second insulating film 122 may include an inorganic film, for example, a silicon oxide film (SiOx), a silicon nitride film (SiNx), or a multilayer film formed therefrom.

A third active layer 140 containing crystalline silicon may be disposed on the second insulating film 122. The third active layer 113 may be formed of crystalline silicon, for example, by forming amorphous silicon over the entire surface of the second insulating film 122, followed by crystallization using laser irradiation.

A third active layer 140 may be disposed on the second insulating film 122 such that the third active layer 140 covers the second insulating film 122. The third insulating film 123 may be used as a gate insulating film of the third transistor T3 for the third active layer 140.

A third gate electrode 150 of the third transistor T3, a first storage electrode 151 of the storage capacitor Cst, and a first light-shielding pattern 152 of the first transistor T1 may be provided on the third insulating film 123.

The third gate electrode 150 of the third transistor T3, the first storage electrode 151 of the storage capacitor Cst, and the first light-shielding pattern 152 of the first transistor T1 may be formed of, for example, a light-shielding conductive metal material. Specifically, the light-shielding conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum TA, neodymium (Nd), or titanium (Ti).

A fourth insulating film 124 may be disposed on the third insulating film 123 such that it covers the third gate electrode 150, the first storage electrode 151, and the first light-shielding pattern 152. The fourth insulating film 124 may function as an insulator between the first and second storage electrodes 151 and 155, and may also function as an interlayer insulating film of the third transistor T1 containing crystalline silicon as the third active layer 140.

The fourth insulating film 124 may contain an inorganic material. The inorganic material may include, for example, a silicon nitride film (SiNx) or a silicon oxide film (SiOx).

A second storage electrode 155 overlapping the first storage electrode 151 may be formed using a conductive metal material on the fourth insulating film 124. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum TA, neodymium (Nd), or titanium (Ti).

Each of the first storage electrode 151 and the second storage electrode 155 may be a single layer or may have a stacked structure of a plurality of different metal materials.

A fifth insulating film 125 may be disposed on the fourth insulating film 124 on which the second storage electrode 155 is disposed. The formation surface on which the second transistor T2 is formed may be planarized using the inorganic insulating material of the fifth insulating film 125. The fifth insulating film 125 may include a single film of an inorganic insulating film including a silicon nitride film (SiNx) or a silicon oxide film (SiOx) or a multilayer film in which other inorganic insulating films are stacked.

The fifth insulating film 125 may be disposed below the second light-shielding pattern 160 of the second transistor T2 to planarize the formation surface of the second light-shielding pattern 160.

A second light-shielding pattern 160 is disposed on the fifth insulating film 125.

A sixth insulating film 126 is disposed on the fifth insulating film 125 on which the second light-shielding pattern 160 is disposed.

The sixth insulating film 126 is disposed under the first and second active layers 165 and 167, functions as a buffer layer, and also flattens the formation surfaces of the first and second active layers 165 and 167. The sixth insulating film 126 may include a single film of an inorganic insulating film including a silicon oxide film (SiOx) or a multiple film in which other inorganic insulating films are stacked along with a silicon oxide film. The sixth insulating film 126 does not emit hydrogen particles during heat treatment or the like and thus prevents deterioration in the reliability of the second active layer 167 of the oxide semiconductor layer disposed adjacent to the sixth insulating film 126 due to hydrogen particles.

The first active layer 165 of the first transistor T1 and the second active layer 167 of the second transistor T2 may be disposed on the sixth insulating film 126. The first active layer 165 and the second active layer 167 may include, for example, an oxide semiconductor material. The oxide semiconductor material may be a combination of at least one metal selected from zinc (Zn), indium (In), gallium GA, tin (Sn), and titanium (Ti) and an oxide. In some cases, a metal with high conductivity, such as iron (Fe), may be further included in the oxide semiconductor material to increase mobility.

More specifically, examples of the oxide semiconductor material constituting the first active layer 165 and the second active layer 167 include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), iron-indium-zinc oxide (FIZO), and the like.

A seventh insulating film 127 may be disposed such that it covers the first active layer 165 and the second active layer 167. The seventh insulating film 127 may include a silicon oxide film or a silicon nitride film. The seventh insulating film 127 may function as a gate insulating film of the first and second transistors T1 and T2.

The first and second gate electrodes 170 and 171 are provided as a conductive metal material on the seventh insulating film 127.

The conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum TA, neodymium (Nd), or titanium (Ti).

The eighth insulating film 128 is disposed such that it covers the first and second gate electrodes 170 and 171.

For example, the eighth insulating film 128 may be formed by stacking a plurality of inorganic insulating films to maintain interlayer insulation between the first gate electrode 170 and the first and second source-drain electrodes 184 and 185, maintain interlayer insulation between the second gate electrode 171 and the third and fourth source-drain electrodes 186 and 187, and flatten the formation surface on which the first to sixth source-drain electrodes 184, 185, 186, 187, 181, and 182 are formed.

A contact hole that penetrates seventh and eighth insulating films 127 and 128 to expose the upper portions of both sides where the first active layer 165 is exposed from the first gate electrode 170 is provided. In the same process, a contact hole that penetrates the seventh and eighth insulating films 127 and 128 to expose the upper portions of both sides where the second active layer 167 is exposed from the second gate electrode 171 is provided. In the same process, a contact hole that penetrates the third to eighth insulating films 123, 124, 125, 126, 127 and 128 to expose the upper portions of both sides where the third active layer 145 is exposed from the third gate electrode 150 is provided. In the same process, a contact hole that penetrates the fifth to eighth insulating films 125, 126, 127 and 128 to expose a portion of the upper portion of the second storage electrode 155 is provided.

A conductive metal material is deposited to provide first and second source-drain electrodes 184 and 185 connected to both sides of a first active layer 165, third and fourth source-drain electrodes 186 and 187 connected to both sides of a second active layer 167, fifth and sixth source-drain electrodes 181 and 182 connected to both sides of a third active layer 145, and a storage connection electrode 183 connected to a second storage electrode 155.

A planarization film 130 may be provided on the eighth insulating film 128 to planarize a surface on which the light emitting element 200 is formed.

The illustrated example is merely provided as an example in which a planarization film including the first to third planarization films 131, 132 and 133 is provided, but the implementation of the present disclosure is not limited thereto and the planarization film may be provided as a single or double layer film.

A first planarization film 131 may be disposed on the eighth insulating film 128 and a contact hole may be provided in the first planarization film 131, and a connection electrode 190 connected to the fourth source/drain electrode 187 through the contact hole may be disposed.

Second and third planarization films 132 and 133 may be further disposed on the first planarization film 131. In addition to the function of planarizing the formation surface of the light emitting element 200, the second and third planarization films 132 and 133 may function to adjust the depth of a recess RS filled with the material of the bank 210 when a part of the configuration of the bank 210 enters the planarization film 130.

For example, the first to third planarization films 131, 132 and 133 may be formed of an organic material. The organic material constituting the first to third planarization films 131, 132 and 133 may include at least one material of an acrylic resin, a phenolic resin, a polyimide resin, an unsaturated polyester resin, a polyamide resin, benzocyclobutene, a polyphenylene resin, or a polyphenylene sulfide resin. Each of the first to third planarization films 131, 132 and 133 is thicker and more advantageous in planarization than each of the first to eighth insulating films 121, 122, 123, 124, 125, 126, 127, and 128.

The bank 210 may include a stack of a first bank layer 211 and a second bank layer 212 that protects the first bank layer 211 and prevents the influence of impurities from the first bank layer 211. The bank 210 may further include a spacer 213 including the same material as the second bank layer 212 in a part of the second bank layer 212.

The first bank layer 211 of the bank 210 may include a black material or a material that blocks at least a portion of visible light. The first bank layer 211 of the bank 210 may prevent external light reflection along with the configuration included in the touch sensor and the color filter unit TCOE.

In addition, the first bank layer 211 includes a light-shielding material to prevent light generated from the light emitting element 200 from being radiated and reflected from the upper side and re-incident on the transistor on the lower side, thereby preventing the transistors T1, T2 and T3 from being abnormally operated by light from the light emitting element 200.

The second bank layer 212 may include a transparent material. The second bank 212 may be a transparent bank, but the implementations of the present disclosure are not limited thereto.

Specifically, the second bank 212 may be disposed on the upper surface or the side surface of the first bank 211. In addition, the second bank 212 may be disposed on at least a part of the first electrode 201 where the first bank 211 is not disposed.

A recess RS may be provided in a part of the planarization film 130 and the material of the first bank layer 211 may fill the recess RS. The material for the first bank layer 211 in the recess RS may shield light that enters the side of the sensor unit in the vertical region between the substrate 110 and the light emitting element 200. Specifically, the recess RS may be provided on the third planarization film 133.

The spacer 213 may first correspond to the deposition mask when the deposition mask corresponds to the upper portion of the substrate 110 when forming multiple layers of the intermediate layer 202 through deposition, thereby preventing the deposition mask from contacting the structure formed on the upper portion of the substrate 110 and preventing damage caused by the deposition mask.

When the connection electrode 190 is omitted, the fourth source drain electrode 187 may be directly connected to the first electrode 201 of the light emitting element 200.

The light emitting element 200 is formed by stacking the first electrode 201, the intermediate layer 202, and the second electrode 203. The first electrode 201 may be independently provided for each subpixel SP and may be separated from adjacent subpixels.

The first electrode 201 may include, for example, a metal material having high reflectivity or a transparent electrode. For example, the first electrode 201 may be formed of multiple layers structure such as a single layer structure of a transparent conductive film such as ITO (indium tin oxide), IZO (indium zinc oxide), TO (tin oxide), or ITZO (indium tin zinc oxide), a stack structure of aluminum (Al) and titanium (Ti) (Ti/Al/Ti), a stacked structure of aluminum (Al) and ITO (ITO/Al/ITO), an APC (Ag/Pd/Cu) alloy, and a stacked structure of an APC alloy and ITO (ITO/APC/ITO), a stacked structure of silver (Ag) and a molybdenum/titanium alloy (Ag/MoTi), or may include a single layer structure formed of one material selected from silver (Ag), aluminum (Al), molybdenum (Mo), gold (Au), magnesium (Mg), calcium (Ca), or barium BA, or two or more alloy materials. When the first electrode 201 includes a reflective electrode, light may be emitted through the second electrode 203 facing the first electrode 201.

The first electrode 201 may include, for example, a reflective electrode and may function to prevent light from being incident on the transistors T1 and T2 below the light emitting element 200. The first electrode 201 may for example, have a stack structure of a first transparent electrode, a reflective electrode, and a second transparent electrode. The second transparent electrode, which is the uppermost electrode of the first electrode 201, may reduce a barrier for hole injection at the interface with the intermediate layer 202 as a dielectric. Here, the first and second transparent electrodes may be transparent oxide electrodes such as ITO or IZO. The reflective electrode may contain silver, a silver alloy such as APC (Ag-Pd-Cu), aluminum, or an aluminum alloy.

In a light emitting display device of a top-emitting type, the second electrode 203 may include a transparent electrode or a thin reflective-transparent electrode that allows light transmission through the second electrode 203. The transparent electrode may be, for example, ITO, IZO, or the like and the reflective/transparent electrode may be, for example, formed of one material selected from silver (Ag), aluminum (Al), molybdenum (Mo), gold (Au), magnesium (Mg), ytterbium (Yb), strontium SR, or an alloy of two or more thereof.

The intermediate layer 202 on the first electrode 201 may include a first common layer CML1 related to holes such as a hole injection layer HIL and a hole transport layer HTL, a light emitting layer EML, a hole blocking layer HBL, and a second common layer CML2 related to electrons such as an electron transport layer ETL and an electron injection layer EIL.

The first bank layer 211 may be provided to cover the edge of the first electrode 201 and an opening of the first bank layer 211 on the first electrode 201 may be defined as a “light emitting portion”. The first bank layer 211 includes a light-shielding organic insulating material and thus maintains a vertical thickness of a certain level or more. The light-shielding organic insulating material of the first bank layer 211 may have a vertical thickness of, for example, 1 μm to 5 μm.

A second bank layer 212 may be further formed on the first bank layer 211 to protect the first bank layer 211 and prevent the inflow of impurities.

The spacer 213 may be locally disposed on a part of the upper surface of the first bank layer 211 rather than the entire upper surface of the first bank layer 211 to prevent the first bank layer 211 or the lower structure under the spacer 213 from collapsing when the deposition mask is applied to the substrate 110 during the deposition process of the intermediate layer 202.

The intermediate layer 202 may include a plurality of functional layers along with the light emitting layer. For example, the intermediate layer 202 may include a hole injection layer, a hole transport layer, a light emitting layer, an electron transport layer, and an electron injection layer. The intermediate layer 202 may include a plurality of stacks, each including a hole transport layer, a light emitting layer, and an electron transport layer, and may also be formed in a tandem structure including a charge generation layer between the stacks. The charge generation layer may include, for example, an n-type charge generation layer and a p-type charge generation layer.

The subpixel SP renders different colors based on the configuration of the light emitting element 200 and the light emitting layer may be patterned using a deposition mask including an opening corresponding to the light emitting portion RA, GA or BA for each subpixel and may be disposed in each subpixel SP.

Functional layers other than the light emitting layer, such as a hole injection layer, a hole transport layer, an electron transport layer, an electron injection layer, and a charge generation layer, may be commonly included in a plurality of subpixels. In addition, the second electrode 203 may also be commonly provided in a plurality of subpixels.

The second electrode 203 may be formed by depositing a transparent electrode such as ITO or IZO, or a reflective transparent electrode such as silver, a silver alloy, magnesium, a magnesium alloy, ytterbium (Yb), or an ytterbium alloy to a small thickness.

A capping layer (not shown) is further formed on the second electrode 203 to protect the second electrode 203 of the light emitting element 200 and increase the luminous efficiency upward.

An encapsulation layer 180 is provided on the second electrode 203 to prevent moisture penetration of the internal structure and protect the internal structure from the outside air.

The encapsulation layer 220 may include, for example, a structure in which a first inorganic encapsulation layer 221, an organic encapsulation layer 222, and a second inorganic encapsulation layer 223 are stacked.

Meanwhile, the touch sensor and color filter unit TCOE described above are provided on the encapsulation layer 220.

In the light emitting display device 1000 of the implementations of the present disclosure, the light-shielding layer 236 has light absorption in the visible light range, and the color filter (237: 237a, 237b, 237c) enables color expression for each light emitting portion RA, GA or BA, and blocks light in the wavelength range other than the transmission wavelength of a predetermined color. Therefore, although external light is incident through the upper protective layer 238, the light is blocked in the area where the light-shielding layer 236 is disposed, and the remaining light in the wavelength region other than the wavelength having selective transmission may be blocked in the area where the color filter (237: 237a, 237b, 237c) is provided, thereby reducing the amount of light incident on the light emitting element among the external light and thus functioning to transmit color and reflect external light.

The light emitting display device of the implementations of the present disclosure also includes a touch wiring including first and second bridge layers 232a and 232b surrounding the light emitting portions RA, GA and BA, and first and second sensor electrodes 235a and 235b, and the light-shielding layer 236 around the light emitting element 200 to prevent the oblique light from being emitted from a predetermined light emitting portion to an adjacent light emitting portion and causing color mixing.

The light emitting display device of the present disclosure is particularly effective in a structure in which the gap between the light emitting portions is narrow and in a high-resolution structure in which the light emitting portions are densely disposed.

Although the bank structure under the encapsulation layer is not changed, because the gap between the light emitting portions is narrow, color mixing between adjacent light emitting portions may be effectively prevented by changing the planar structure of the touch wiring disposed on the encapsulation layer.

The light emitting display device of the implementations of the present disclosure may prevent color mixing between adjacent light emitting portions through the configuration in which the touch wiring surrounds the light emitting portion.

The light emitting display device of the implementations of the present disclosure may prevent external light from being recognized through the touch wiring, the light-shielding layer, and the color filter disposed on the upper part of the encapsulation layer, omits the polarizing plate and thus improves transmittance.

The light emitting display device of the implementations of the present disclosure has a planar shape in which the touch wiring disposed on the upper part of the encapsulation layer is disposed around (e.g., surrounds) each light emitting portion, regardless of whether or not a leakage current prevention structure is provided in the structure under the encapsulation layer, thereby preventing color mixing between adjacent light emitting portions.

The light emitting display device of the implementations of the present disclosure may reduce the thickness of the light-shielding layer disposed on the upper part of the touch wiring and reduce the area occupied by the light-shielding layer in proportion to the thickness reduction, thereby increasing the transmittance through the component disposed on the upper part of the encapsulation layer because the touch wiring has the ability to prevent color mixing between adjacent light emitting portions.

The light emitting display device of the implementations of the present disclosure may increase the degree of freedom in the arrangement of the light-shielding layer even in a structure in which a transmission area is provided in an area corresponding to a sensor or camera on the lower side of the substrate.

By changing the structure of the touch wiring without increasing the structure, the display device of the implementations of the present disclosure may prevent color mixing between adjacent light emitting portions and omit a polarizing plate, reduce the thickness of the light-shielding layer, reduce the production energy required to produce the display device, and reduce the use of hazardous production materials or regulated substances, thus being advantageous for recycling and more advantageous for realizing an eco-friendly display device.

The display device according to the implementations of the present disclosure may improve visibility by preventing color mixing, and may realize ESG (environmental/social/governance) goals through the effect of reducing production energy based on process optimization.

Hereinafter, another plan shape of the touch wiring will be described.

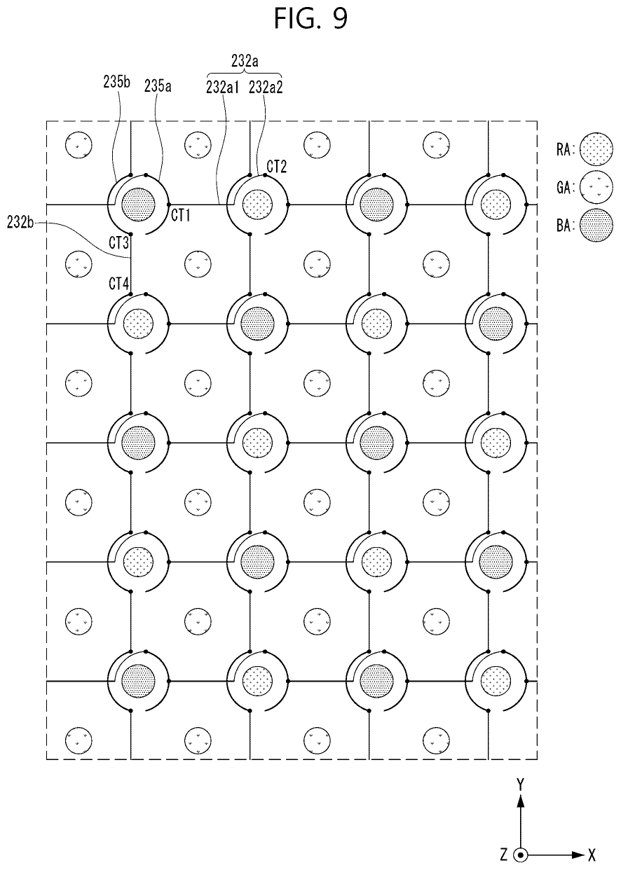

FIGS. 9 to 12 are plan views illustrating an area not overlapping a sensor unit of FIG. 1 according to another implementation.

As shown in FIG. 9, in the red light emitting portion RA or the blue light emitting portion BA, the first sensor electrode 235a and the second sensor electrode 235b are disposed on the right and left sides of each light emitting portion RA or BA and face each other, and the first and second sensor electrodes 235a and 235b may form overall a circle surrounding the red light emitting portion RA or the blue light emitting portion BA. Here, each of the first and second sensor electrodes 235a and 235b is disposed in the shape of a curve spaced apart from each light emitting portion by a predetermined distance.

When the first and second sensor electrodes 235a and 235b are disposed on the same layer, the first sensor electrode 235a and the second sensor electrode 235b are separated from each other for electrical separation.

Each first sensor electrode 235a adjacent to one light emitting portion and the next light emitting portion in the X-axis direction has an island shape and a first bridge layer 232a may be provided in a different layer from the first sensor electrode 235a to electrically connect the first sensor electrodes 235a adjacent to different light emitting portions. Since the second sensor electrode 235b is disposed between one first sensor electrode 235a and another first sensor electrode 235a adjacent thereto in the X-axis direction, the first bridge layer 232a overlaps the second sensor electrode 235b disposed on the path between the adjacent first sensor electrodes 235a, but is not connected.

When the first and second sensor electrodes 235a and 235b are disposed on the same layer, the first sensor electrode 235a and the second sensor electrode 235b are separated from each other for electrical separation.

Each first sensor electrode 235a adjacent to one light emitting portion and the next light emitting portion in the X-axis direction has an island shape and a first bridge layer 232a may be provided in a different layer from the first sensor electrode 235a to electrically connect the first sensor electrodes 235a adjacent to different light emitting portions. Since the second sensor electrode 235b is disposed between one first sensor electrode 235a and another first sensor electrode 235a adjacent thereto in the X-axis direction, the first bridge layer 232a overlaps the second sensor electrode 235b disposed in the path between the adjacent first sensor electrodes 235a, but is not connected.

Since the first bridge layer 232a passes through the light emitting portion when connecting one first sensor electrode 235a to the next first sensor electrode 235a adjacent thereto in a straight line in the X-axis direction, the first bridge layer 232a is disposed to be adjacent to the light emitting portion BA, GA or RA, but bypass the light emitting portion so as to prevent loss of opening of the light emitting portion.

For example, the first bridge layer 232a between adjacent blue light emitting portion BA and red light emitting portion RA may include a first linear portion 232a1 that is connected to the first sensor electrode 235a adjacent to the blue light emitting portion BA through a first contact portion CT1, overlaps the second sensor electrode 235b disposed adjacent to the left side of the red light emitting portion RA, is not connected to the second sensor electrode 235b, and extends in the X-axis direction, and a second linear portion 232a2 that is connected to the first sensor electrode 235a that is disposed adjacent to the right side of the red light emitting portion RA from the first linear portion 232a1 through a second contact portion CT2. The regions of the first contact portion CT1 and the second contact portion CT2 may be changed by changing the overlapping area of the first bridge layer 232a in a region where the first sensor electrode 235a is adjacent to the neighboring light emitting portions. As shown in FIG. 8, the first linear portion 232a1 may be a straight line and the second linear portion 232a2 may be a curve.

Here, the second linear portion 232a2 of the first bridge layer 232a may be disposed closer to the light emitting portions RA and BA than the second sensor electrode 235b.

In some cases, the first transport electrode Tx may be formed by omitting the second linear portion 232a2 from the first bridge layer 232a and extending the first sensor electrode 235a in the same plane shape as the second linear portion 232a2, and may be provided with a second contact portion CT2 in which one end of the extended first sensor electrode 235a and the first linear portion of the first bridge layer are connected. In other words, the second linear portion may be disposed in a layer where a sensor electrode is formed, not a bridge layer.

In addition, the island-shaped second sensor electrodes 235b disposed in the Y-axis direction are connected to the second bridge layer 232b through a third contact portion CT3 disposed on one side thereof and a fourth contact portion CT4 disposed on the other side thereof, as shown in FIG. 6.

The first to fourth contact portions CT1, CT2, CT3 and CT4 may be provided in the form of a contact hole within the first and second touch intermediate insulating films 233 and 244 as shown in FIGS. 4 to 7.

The touch wiring of FIG. 9 may have a structure in which at least one of the first and second bridge layers 232a and 232b or the first and second sensor electrodes 235a and 235b is disposed between adjacent light emitting portions, thus preventing color mixing between the adjacent light emitting portions.

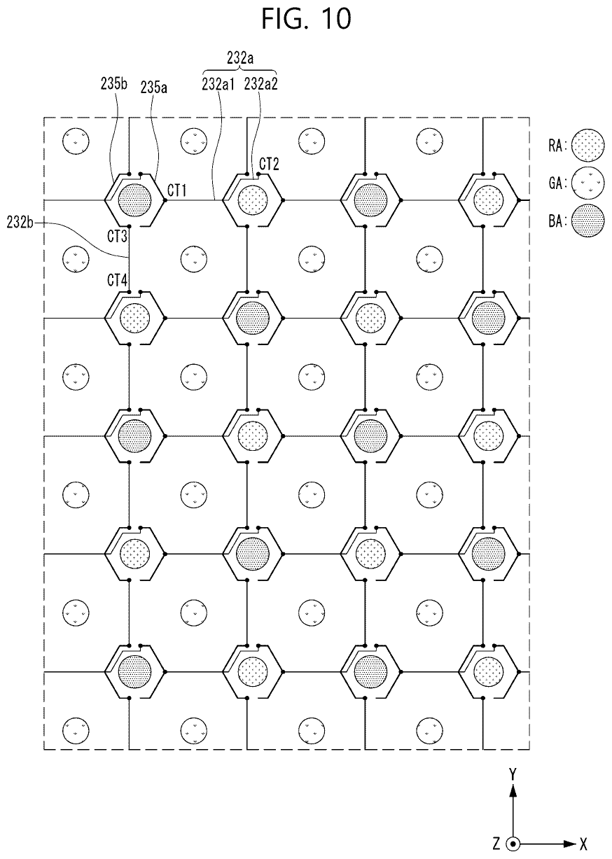

In the light emitting display device of FIG. 10, the first sensor electrode 235a and the second sensor electrode 235b are joined together to form a hexagonal shape in each light emitting portion RA or BA. The first and second sensor electrodes 235a and 235b are disposed with four sides on the right and left sides, respectively, and face each other, but the first and second sensor electrodes 235a and 235b surround the red light emitting portion RA or the blue light emitting portion BA to form an overall hexagonal shape. Here, each of the first and second sensor electrodes 235a and 235b includes a first side in the X-axis direction, a second side connected to the first side in the first diagonal direction, a third side connected to the second side in the second diagonal direction and a fourth side connected to the third side in the X-axis direction.

The touch wiring of FIG. 10 has a structure in which at least one of the first and second bridge layers 232a and 232b and the first and second sensor electrodes 235a and 235b is disposed between adjacent light emitting portions to prevent mixed-color light emission between the adjacent light emitting portions.

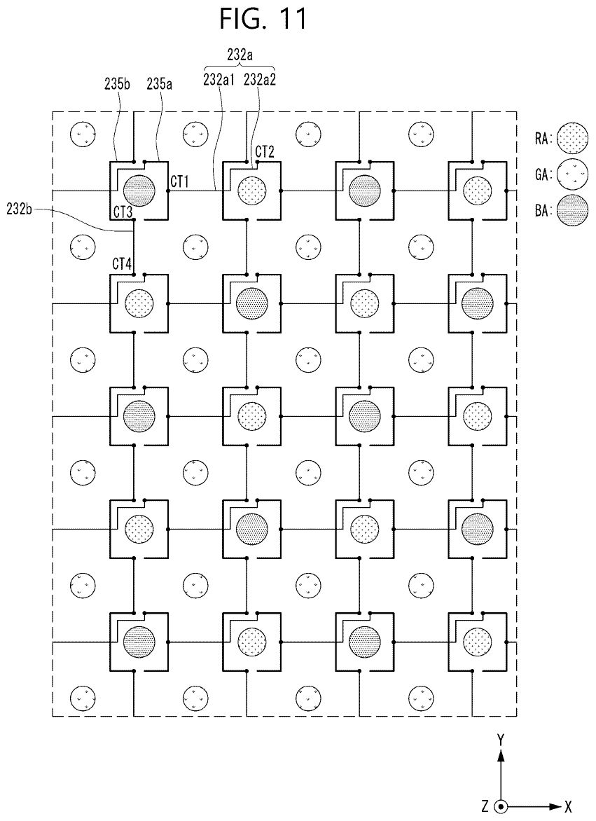

In the light emitting display device of FIG. 11, the first sensor electrode 235a and the second sensor electrode 235b are joined together to form a square shape in each light emitting portion RA or BA. The first and second sensor electrodes 235a and 235b are disposed with three sides on the right and left sides, respectively, and face each other, but the first and second sensor electrodes 235a and 235b surround the red light emitting portion RA or the blue light emitting portion BA to form an overall square shape. Here, each of the first and second sensor electrodes 235a and 235b includes a first side in the X-axis direction, a second side connected to the first side in the Y-axis direction, and a third side connected to the second side in the X-axis direction.

The touch wiring of FIG. 11 also has a structure in which at least one of the first and second bridge layers 232a and 232b and the first and second sensor electrodes 235a and 235b is disposed between adjacent light emitting portions to prevent mixed-color light emission between the adjacent light emitting portions.

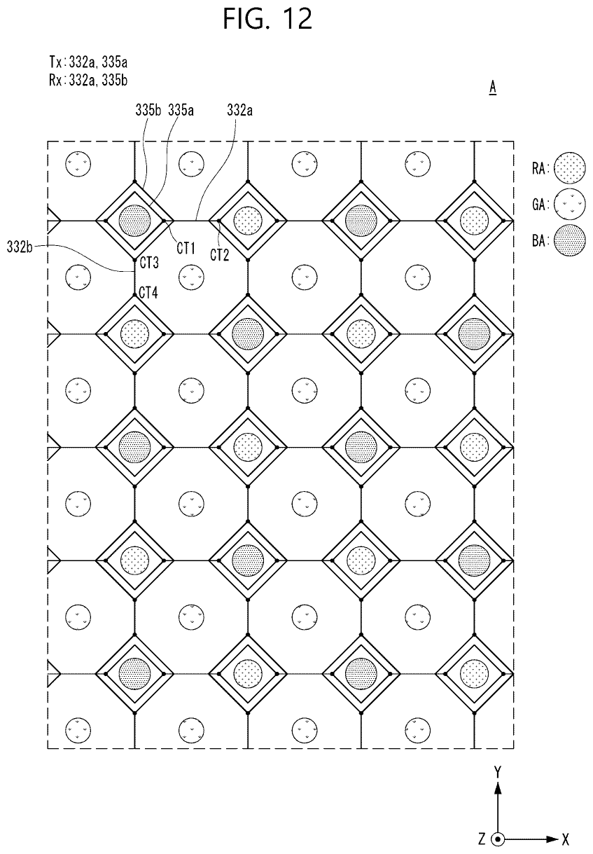

The touch wiring of FIG. 12 has a structure in which the first and second sensor electrodes 335a and 335b are disposed in an independent closed-loop shape for the red light emitting portion RA and the blue light emitting portion BA.

The transport electrodes Tx are disposed apart from each other in the X-axis direction and include a plurality of first sensor electrodes 335a provided in the form of islands and a first bridge layer 332a connecting the adjacent first sensor electrodes 335a for the respective light emitting portions RA and BA.

The transmission electrodes Rx are disposed apart from each other in the Y-axis direction and include a plurality of second sensor electrodes 335b provided in the form of islands and a second bridge layer 332b connecting the adjacent second sensor electrodes 335b.

In the illustrated example, the first sensor electrode 335a is disposed on the inside and the second sensor electrode 335b is disposed on the outside. In this case, the first sensor electrode 335a disposed inside each of the red light emitting portion RA and the blue light emitting portion BA is provided with a first contact portion CT1 on one side and a second contact portion CT2 on the other side in the X-axis direction, and is connected by a first bridge layer 332a connecting adjacent first sensor electrodes 335a. The first bridge layer 332a may be disposed in a straight line in the X-axis direction. In addition, the first bridge layer 332a may overlap and be unconnected to the second sensor electrode 335b disposed outside each of the red light emitting portion RA and the blue light emitting portion BA on the path.

The second sensor electrode 335b may be provided with a third contact portion CT3 on one side and a fourth contact portion CT4 on the other side, respectively, in the Y-axis direction. The second sensor electrode 335b disposed relatively outside the red light emitting portion RA and the blue light emitting portion BA may be connected through the second bridge layer 332a disposed between the third and fourth contact holes CT3 and CT4 between the adjacent second sensor electrodes 335b without overlapping the first sensor electrode 335a.

In the structure of the touch wiring of FIG. 12, the first bridge layer 332a or the second bridge layer 332b is disposed between the green light emitting portions GA, so that light leakage between the green light emitting portions GA that are light emitting portions of the same color as well as between light emitting portions with different colors can be prevented.

As shown in FIG. 12, at least one of the first and second bridge layers 332a and 332b and the first and second sensor electrodes 335a and 335b is provided between the light emitting portions RA, GA and BA that are different from each other. The light generated from the light emitting portions RA, GA and BA may be direct light directed upward as well as oblique light. When such oblique light is observed from an adjacent light emitting portion, it may be mixed with the direct light from the adjacent light emitting portion, resulting in mixed light emission, which may deteriorate the image quality. The first and second bridge layers 332a and 332b and the first and second sensor electrodes 335a and 335b of the light emitting display devices according to the implementations of the present disclosure are disposed at least partially between adjacent light emitting portions to block light emitted in a diagonal direction from one of the light emitting portions.

The first and second sensor electrodes 335a and 335b are disposed in duplicate between adjacent red light emitting portions RA and blue light emitting portions BA in the X-axis or Y-axis direction, and also the first bridge layer 332a or the second bridge layer 332b is disposed.

Between the red light emitting portion RA and the green light emitting portion GA, first and second sensor electrodes 335a and 335b surrounding the red light emitting portion RA are disposed.

Between the blue light emitting portion BA and the green light emitting portion GA, first and second sensor electrodes 335a surrounding the blue light emitting portion BA are disposed.

Between the green light emitting portions GA, a first bridge layer 332a or a second bridge layer 332b is disposed.

That is, according to the implementation shown in FIG. 12, at least one of the first and second sensor electrodes 335a and 335b and the first and second bridge layers 332a and 332b is disposed between any light emitting portions, thus preventing mixed-color emission.

It is possible to prevent the cross-sectional light from each light emitting portion BA or RA from being recognized by an adjacent light emitting portion.

Hereinafter, the area B where a sensor including a camera or an infrared sensor is placed in the active area AA will be described. The sensor unit B including a camera or an infrared sensor may be provided as a separate configuration on the lower side of the substrate 110.

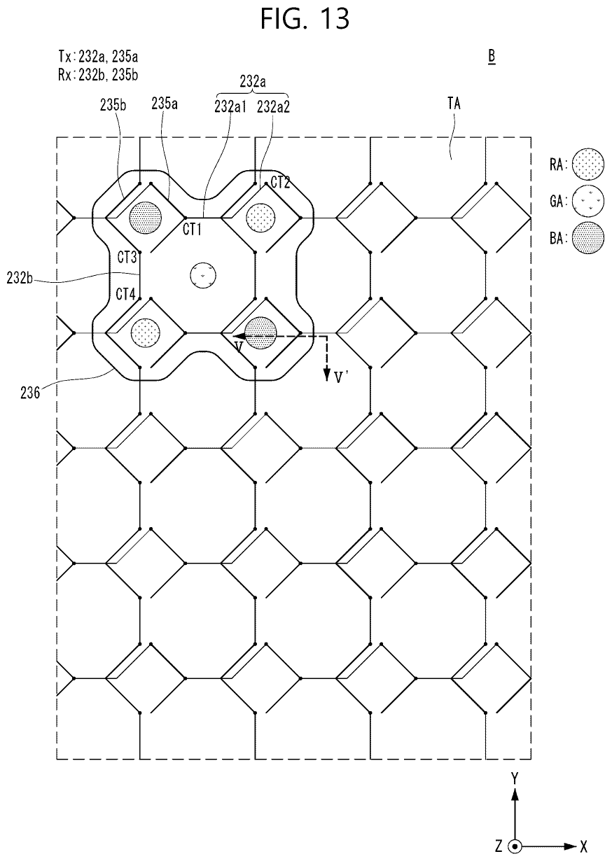

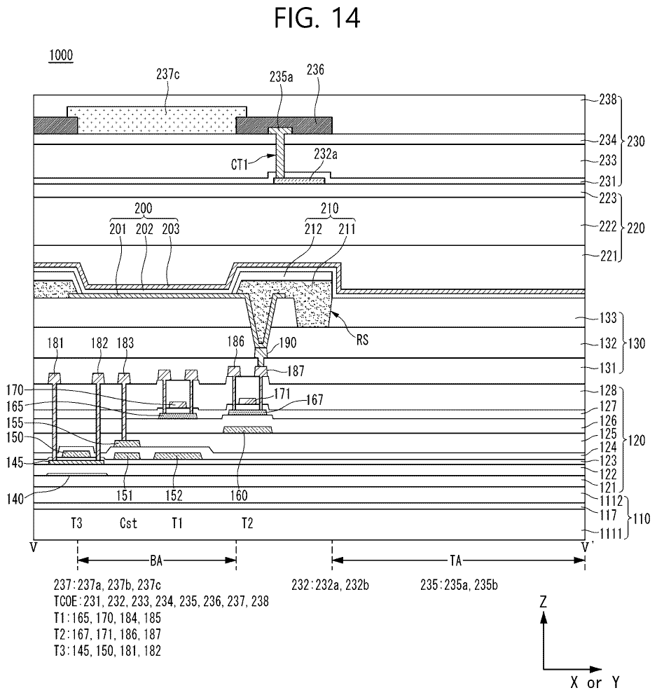

FIG. 13 is a plan view illustrating the area B overlapping with the sensor of FIG. 1 and FIG. 14 is a cross-sectional view taken along the V-V′ line of FIG. 13.

In the light emitting display device 1000, the sensor unit B including a camera or an infrared sensor may be disposed in the active area AA for sensing sensitivity and may be disposed on the lower side of the substrate 110. In addition, in order to sense light incident from the upper protective layer 238 and increase sensitivity, as shown in FIGS. 12 and 13, the sensor unit B may include an area overlapping a transmissive portion TA in addition to the light emitting portions RA, GA and BA.

The configuration of the light emitting portion RA, GA or BA disposed in the sensor unit B is the same as that of the light emitting portion described with reference to FIGS. 3 to 7, and thus the description thereof is omitted.

At least the first electrode 201, the first bank layer 211, the transistors T1, T2 and T3, the storage capacitor Cst, or the like included in the light emitting portion RA, GA or BA for light transmission may be omitted from the transmission area TA.

Here, light is vertically incident on the transmission area TA from the upper protective layer 238 toward the lower side of the substrate 110 and the first bank layer 211 is provided with a deep recess RS in the planarization film 130 to prevent the light traveling vertically from being transmitted to the side in the configuration on the substrate 110, thereby preventing the light from affecting the transistors T1, T2 and T3 inside.

In the light emitting display device 1000 according to another implementation of the present disclosure, the recess RS is provided up to a part of the insulating film 120 that is greater than the entire thickness of the planarization film 130, and the material of the first bank layer 211 in the recess RS is filled to more effectively prevent the transmission of light to the side according to the arrangement of the transmission area in the sensor unit B.

As shown in FIG. 13, the light-shielding layer 236 may be omitted from the area where the transmission area TA is disposed. Although the light-shielding layer 236 is omitted, the first and second bridge layers 232a and 232b and the first and second sensor electrodes 235a and 235b between the transmission areas TA are each formed of thin lines of low-reflectivity metal and thus do not impede the sensing sensitivity of the sensor unit B.

In some cases, a light-shielding layer 236 may be further provided with a line width corresponding to the first and second bridge layers 232a and 232b and the first and second sensor electrodes 235a and 235b between the transmission areas TA to prevent reflection by the first and second bridge layers 232a and 232b and the first and second sensor electrodes 235a and 235b.

The illustrated example is merely provided as an example in which the first and second bridge layers 232a and 232b and the first and second sensor electrodes 235a and 235b are disposed in the transmission area TA to provide touch sensing. In some cases, when touch sensing is not required in addition to light sensing by a camera or an infrared sensor in the sensor unit B, the first and second bridge layers 232a and 232b and the first and second sensor electrodes 235a and 235b may be omitted in the area adjacent to the transmission area TA to further improve the light sensing sensitivity.

Meanwhile, the illustrated example shows a configuration in which the intermediate layer 202 and the second electrode 203 extend to the transmission area TA. When the intermediate layer 202 includes components such as a hole injection layer, a hole transport layer, a light emitting layer, an electron transport layer, and an electron injection layer, the light emitting layer may be patterned and thus be omitted from the transmission area TA. To further improve the light sensing sensitivity of the transmission area TA, the second electrode 203 may be omitted from the transmission area TA.

In some cases, at least a part of the insulating film 120 and the planarizing film 130 provided in the transmission area TA may be omitted to increase the pure transmittance of the transmission area TA.

The light emitting display device of the implementations of the present disclosure may reduce the thickness of the light-shielding layer disposed on the upper part of the touch wiring and reduce the area occupied by the light-shielding layer in proportion to the thickness reduction, thereby increasing the transmittance through the component disposed on the upper part of the encapsulation layer because the touch wiring has the ability to prevent color mixing between adjacent light emitting portions.

The light emitting display device of the implementations of the present disclosure may increase the degree of freedom in the arrangement of the light-shielding layer even in a structure in which a transmission area is provided in an area corresponding to a sensor or camera on the lower side of the substrate.

By changing the structure of the touch wiring without increasing the structure, the display device of the implementations of the present disclosure may prevent color mixing between adjacent light emitting portions and omit a polarizing plate, reduce the thickness of the light-shielding layer, reduce the production energy for producing the display device, and reduce the use of hazardous production materials or regulated substances, thus being advantageous for recycling and more advantageous for realizing an eco-friendly display device.

The display device according to the implementations of the present disclosure may improve visibility by preventing color mixing, and may realize ESG (environmental/social/governance) goals through the effect of reducing production energy based on process optimization.

A light emitting display device according to one implementation of the present disclosure may comprise a bank to define a plurality of light emitting portions spaced apart from each other on a substrate, a light emitting element at each of the light emitting portions, the light emitting element comprising a first electrode, an intermediate layer on the first electrode and a second electrode on the intermediate layer, an encapsulation layer over the light emitting element, a touch wiring on the encapsulation layer, the touch wiring comprising a linear portion longer than a diameter of any one of the light emitting portions or a side of any one of the light emitting portions between the plurality of light emitting portions on a plane, a light-shielding layer to cover the touch wiring on the encapsulation layer and a color filter layer on the encapsulation layer corresponding to each of the light emitting portions.

In a light emitting display device according to one implementation of the present disclosure, the light emitting portions may have a curved outline adjacent to the touch wiring and the linear portion of the touch wiring is disposed along the outline of the curve.

In a light emitting display device according to one implementation of the present disclosure, the linear portion of the touch wiring may be longer than the light emitting portion having a longer diameter or a longer side among the adjacent light emitting portions.

In a light emitting display device according to one implementation of the present disclosure, the linear portion of the touch wiring may block light emitted in a diagonal direction from one of the light emitting portions.

In a light emitting display device according to one implementation of the present disclosure, the touch wiring may surround the plurality of light emitting portions.

In a light emitting display device according to one implementation of the present disclosure, the touch wiring may comprise a first touch wiring and a second touch wiring, and the first touch wiring comprises a plurality of first sensor electrodes disposed in a first direction and spaced apart from each other, and a first bridge layer connecting one first sensor electrode to other first sensor electrodes adjacent thereto in a different layer, the second touch wiring comprises a plurality of second sensor electrodes disposed in a second direction intersecting the first direction and spaced apart from each other, and a second bridge layer connecting one second sensor electrode to other second sensor electrodes adjacent thereto in a different layer, and each first sensor electrode and each second sensor electrode surround at least a part of any one of the light emitting portions.

In a light emitting display device according to one implementation of the present disclosure, the first sensor electrode surrounding the first light emitting portion on one side, the second sensor electrode surrounding the second light emitting portion on the other side, and the first bridge layer which is connected to the first sensor electrode, passing between the first sensor electrode and the second sensor electrode, overlapping the second sensor electrode while not being connected, and disposed closer to the second light emitting portion than the second sensor electrode, may be disposed between a first light emitting portion and a second light emitting portion that emit different colors in the first direction.

In a light emitting display device according to one implementation of the present disclosure, the second touch wiring may be disposed between the light emitting portions that emit different colors in the second direction. The first bridge layer of the first touch wiring may be disposed closer to one of the light emitting portions that emit different colors than the second sensor electrode of the second touch wiring.

In a light emitting display device according to one implementation of the present disclosure, the touch wiring comprises a first touch wiring and a second touch wiring, the first touch wiring comprises a plurality of first sensor electrodes disposed in a first direction and spaced apart from each other, and a first bridge layer connecting one first sensor electrode to other adjacent first sensor electrodes adjacent thereto in a different layer, the second touch wiring comprises a plurality of second sensor electrodes disposed in a second direction intersecting the first direction and spaced apart from each other, and a second bridge layer connecting one second sensor electrode to other adjacent second sensor electrodes adjacent thereto in a different layer. And each first sensor electrode and each second sensor electrode may have different closed loops for one light emitting portion.

In a light emitting display device according to one implementation of the present disclosure, the first bridge layer and the second bridge layer may be disposed on the same layer, and the first touch wiring and the second touch wiring may be disposed on the same layer.

In a light emitting display device according to one implementation of the present disclosure, the first touch wiring and the second touch wiring may comprise a metal or alloy including at least one of titanium, molybdenum, chromium, or aluminum.

In a light emitting display device according to one implementation of the present disclosure, the plurality of light emitting portions may comprise a plurality of first light emitting portions that emit light of a first wavelength, a plurality of second light emitting portions that emit light of a shorter wavelength than the first wavelength and a plurality of third light emitting portions that emit light of a longer wavelength than the first wavelength. The plurality of second light emitting portions and the plurality of third light emitting portions may be each surrounded by the first sensor electrode and the second sensor electrode. The first bridge layer or the second bridge layer may be disposed between the plurality of first light emitting portions.

In a light emitting display device according to one implementation of the present disclosure, the light-shielding layer may surround the upper and side surfaces of each of the first and second sensor electrodes.

In a light emitting display device according to one implementation of the present disclosure, the first and second sensor electrodes, an area of the light-shielding layer surrounding the side surfaces of the first and second sensor electrodes and the color filter layer may be disposed on the same plane, and the upper surface of the light-shielding layer is lower than the color filter layer.

A light emitting display device according to one implementation of the present disclosure may further comprise a touch buffer layer between the encapsulation layer and the first and second bridge layers, a touch intermediate insulating film between the first and second bridge layers and the first and second sensor electrodes and an upper protective layer on the light-shielding layer and the color filter layer.

In a light emitting display device according to one implementation of the present disclosure, the bank may comprise a first bank layer containing a light-shielding material.

In a light emitting display device according to one implementation of the present disclosure, the bank may further comprise a second bank layer on the first bank layer.

A light emitting display device according to one implementation of the present disclosure may further comprise a sensor under the substrate. The substrate may comprise an active area including the plurality of light emitting portions and a non-active area outside the active area, and the sensor may overlap a transmission area in the active area of the substrate.

A light emitting display device according to one implementation of the present disclosure may further comprise a transistor and a planarization film to protect the transistor between the substrate and the light emitting element. The planarization film may have a recess, and the bank may fill the recess.

In a light emitting display device according to one implementation of the present disclosure, the transistor may comprise an active layer including an oxide semiconductor.

The light emitting display device of the present disclosure has the following effects.

The light emitting display device may reduce leakage current between adjacent subpixels by providing a pattern structure such as a trench in the pixel definition film defining the light emitting portion of the light emitting element, thereby eliminating mixed-color light emission caused by leakage current. The light emitting display device of the implementations of present disclosure may prevent mixed-color light emission between adjacent light emitting portions by disposing the touch wiring to surround the light emitting portion.

The light emitting display device of the implementations of the present disclosure may prevent external light from being recognized through the touch wiring, the light-shielding layer, and the color filter disposed on the upper part of the encapsulation layer, omits the polarizing plate and thus improves the transmittance.

The light emitting display device of the implementations of the present disclosure has a planar shape in which the touch wiring disposed on the upper part of the encapsulation layer surrounds each light emitting portion, regardless of whether or not a leakage current prevention structure is provided in the structure under the encapsulation layer, thereby preventing color mixing between adjacent light emitting portions.

The light emitting display device of the implementations of the present disclosure may reduce the thickness of the light-shielding layer disposed on the upper part of the touch wiring and reduce the area occupied by the light-shielding layer in proportion to the thickness reduction, thereby increasing the transmittance through the component disposed on the upper part of the encapsulation layer because the touch wiring has the ability to prevent color mixing between adjacent light emitting portions.

The light emitting display device of the implementations of the present disclosure may increase the degree of freedom in the arrangement of the light-shielding layer even in a structure in which a transmission area is provided in an area corresponding to a sensor or camera on the lower side of the substrate.

By changing the structure of the touch wiring without increasing the structure, the display device of the implementations of the present disclosure may prevent color mixing between adjacent light emitting portions and omit a polarizing plate, reduce the thickness of the light-shielding layer, reduce the production energy for producing the display device, and reduce the use of hazardous production materials or regulated substances, thus being advantageous for recycling and more advantageous for realizing an eco-friendly display device.

The display device according to the implementations of the present disclosure may improve visibility by preventing color mixing, and may realize ESG (environmental/social/governance) goals through the effect of reducing production energy based on process optimization.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting display device comprising:
a bank that defines a plurality of light emitting portions spaced apart from each other on a substrate;
a light emitting element at each of the light emitting portions, the light emitting element comprising a first electrode, an intermediate layer on the first electrode and a second electrode on the intermediate layer;
an encapsulation layer disposed over the plurality of light emitting portions;
a touch wiring disposed on the encapsulation layer and comprising a linear portion that is disposed, in a planar view, between adjacent light emitting portions, wherein the linear portion of the touch wiring is longer than a diameter of any one of the adjacent light emitting portions or a length of a side of any one of the adjacent light emitting portions;
a light-shielding layer that covers the touch wiring on the encapsulation layer; and
a color filter layer on the encapsulation layer and corresponding to each of the light emitting portions.

2. The light emitting display device according to claim 1, wherein each of the light emitting portions has a curved outline adjacent to the touch wiring, and
wherein the linear portion of the touch wiring is disposed along the curved outline of the light emitting portion.

3. The light emitting display device according to claim 1, wherein the linear portion of the touch wiring is longer than a light emitting portion having a longer diameter or a longer side among the adjacent light emitting portions.

4. The light emitting display device according to claim 1, wherein the linear portion of the touch wiring is configured to block light emitted in a diagonal direction from one of the light emitting portions.

5. The light emitting display device according to claim 1, wherein the touch wiring is disposed around each of the plurality of light emitting portions.

6. The light emitting display device according to claim 1, wherein the touch wiring comprises a first touch wiring and a second touch wiring, and
the first touch wiring comprises a plurality of first sensor electrodes disposed in a first direction and spaced apart from each other, and a first bridge layer connecting one first sensor electrode to other first sensor electrodes adjacent thereto in a different layer,
the second touch wiring comprises a plurality of second sensor electrodes disposed in a second direction intersecting the first direction and spaced apart from each other, and a second bridge layer connecting one second sensor electrode to other second sensor electrodes adjacent thereto in a different layer, and
each first sensor electrode and each second sensor electrode is disposed around at least a part of any one of the light emitting portions.

7. The light emitting display device according to claim 6, wherein the first sensor electrode is disposed around the first light emitting portion on one side,
the second sensor electrode is disposed around the second light emitting portion on the other side, and
the first bridge layer is connected to the first sensor electrode, passes between the first sensor electrode and the second sensor electrode, overlaps the second sensor electrode while not being connected, and is disposed closer to the second light emitting portion than the second sensor electrode,
wherein the first sensor electrode, the second sensor electrode, and the first bridge layer are disposed between a first light emitting portion and a second light emitting portion that emit different colors in the first direction.

8. The light emitting display device according to claim 6, wherein the second touch wiring is disposed between the light emitting portions that emit different colors in the second direction and
the first bridge layer of the first touch wiring is disposed closer to one of the light emitting portions that emit different colors than the second sensor electrode of the second touch wiring.

9. The light emitting display device according to claim 1, wherein the touch wiring comprises a first touch wiring and a second touch wiring,
the first touch wiring comprises a plurality of first sensor electrodes disposed in a first direction and spaced apart from each other, and a first bridge layer connecting one first sensor electrode to other adjacent first sensor electrodes adjacent thereto in a different layer,
the second touch wiring comprises a plurality of second sensor electrodes disposed in a second direction intersecting the first direction and spaced apart from each other, and a second bridge layer connecting one second sensor electrode to other adjacent second sensor electrodes adjacent thereto in a different layer, and
each first sensor electrode and each second sensor electrode have different closed loops surrounding one light emitting portion.

10. The light emitting display device according to claim 6, wherein the first bridge layer and the second bridge layer are disposed on the same layer, and
the first touch wiring and the second touch wiring are disposed on the same layer.

11. The light emitting display device according to claim 6, wherein the first touch wiring and the second touch wiring comprise a metal or alloy including at least one of titanium, molybdenum, chromium, or aluminum.

12. The light emitting display device according to claim 9, wherein the plurality of light emitting portions comprise:
a plurality of first light emitting portions that emit light of a first wavelength;
a plurality of second light emitting portions that emit light of a shorter wavelength than the first wavelength; and
a plurality of third light emitting portions that emit light of a longer wavelength than the first wavelength,
wherein the plurality of second light emitting portions and the plurality of third light emitting portions are each surrounded by the first sensor electrode and the second sensor electrode, and
the first bridge layer or the second bridge layer is disposed between the plurality of first light emitting portions.

13. The light emitting display device according to claim 6, wherein the light-shielding layer surrounds the upper and side surfaces of each of the first and second sensor electrodes.

14. The light emitting display device according to claim 6, wherein the first and second sensor electrodes, an area of the light-shielding layer surrounding the side surfaces of the first and second sensor electrodes and the color filter layer are disposed on the same plane, and
wherein the upper surface of the light-shielding layer is lower than the color filter layer.

15. The light emitting display device according to claim 6, further comprising:
a touch buffer layer between the encapsulation layer and the first and second bridge layers;
a touch intermediate insulating film between the first and second bridge layers and the first and second sensor electrodes; and
an upper protective layer on the light-shielding layer and the color filter layer.

16. The light emitting display device according to claim 1, wherein the bank comprises a first bank layer containing a light-shielding material.

17. The light emitting display device according to claim 16, wherein the bank further comprises a second bank layer on the first bank layer.

18. The light emitting display device according to claim 1, further comprising a sensor under the substrate,
wherein the substrate comprises an active area including the plurality of light emitting portions and a non-active area outside the active area, and
wherein the sensor overlaps a transmission area in the active area of the substrate.

19. The light emitting display device according to claim 1, further comprising a transistor and a planarization film to protect the transistor between the substrate and the light emitting element,
wherein the planarization film has a recess, and
wherein the bank fills the recess.

20. A light emitting display device comprising:
a substrate;
a plurality of light emitting portions spaced apart from each other on the substrate, each light emitting portion comprising a first electrode, an intermediate layer on the first electrode and a second electrode on the intermediate layer; and
an encapsulation layer disposed over the plurality of light emitting portions,
wherein for adjacent light emitting portions of the plurality of light emitting portions:
the adjacent light emitting portions are spaced apart from each other by a bank disposed below the encapsulation layer,
a touch wiring is disposed on the encapsulation layer over the bank, wherein the touch wiring extends, in a planar view, through a region between the adjacent light emitting portions,
a light-shielding layer covers the touch wiring on the encapsulation layer, and
a color filter layer is disposed on the encapsulation layer over each of the light emitting portions.
